(19) United States
(12) Patent Application Publication
(10) Pub. No.: US 2025/0338511 A1
(43) Pub. Date: Oct. 30, 2025

(54) SEMICONDUCTOR DEVICE

(71) Applicant: SK hynix Inc., Icheon-si Gyeonggi-do (KR)

(72) Inventors: Su Hyun OH, Icheon-si Gyeonggi-do (KR); Jin Hyung LEE, Icheon-si Gyeonggi-do (KR); Chang Kwon LEE, Icheon-si Gyeonggi-do (KR)

(73) Assignee: SK hynix Inc., Icheon-si Gyeonggi-do (KR)

(21) Appl. No.: 18/884,826

(22) Filed: Sep. 13, 2024

(30) Foreign Application Priority Data
Apr. 24, 2024 (KR) 10-2024-0055010

(51) Int. Cl. H10B 80/00; G11C 29/10; H01L 25/065; H01L 25/18

(52) U.S. Cl. CPC H10B 80/00; G11C 29/10; H01L 25/0657; H01L 25/18; H01L 2225/06513; H01L 2225/06541; H01L 2225/06596

(57) ABSTRACT

A semiconductor device includes a base chip and a memory chip stacked with first, second, third, and fourth signal paths, each signal path extending through the memory chip into the base chip. The base chip and the memory chip are configured to simultaneously drive the first signal path and the third signal path after the start of an even scan operation and then simultaneously drive the second signal path and the fourth signal path after the start of an odd scan operation. The base chip is configured to generate first, second, third, and fourth fail detection signals that detect a connection failure of the first, second, third, and fourth signal paths based on a logic level at which the first, second, third, and fourth signal paths are driven.

### CROSS-REFERENCE TO RELATED APPLICATION

The present application claims priority under 35 U.S.C. § 119(a) to Korean Patent Application No. 10-2024-0055010, filed in the Korean Intellectual Property Office on Apr. 24, 2024, the entire contents of which application is incorporated herein by reference.

### BACKGROUND

The present disclosure relates to a semiconductor device that detects a connection failure between signal paths along which a plurality of chips is stacked.

As technology for manufacturing semiconductor devices is developed, packaging technology for including a plurality of memory chips in semiconductor devices is gradually evolving, resulting in semiconductor devices having higher performance. In packaging technologies for implementing semiconductor devices, a technology regarding a three-dimensional structure in which a plurality of memory chips is vertically stacked, away from a two-dimensional structure in which a plurality of memory chips is disposed on a printed circuit board (PCB) in a two-dimensional way, is variously developed. A semiconductor device having a three-dimensional structure may be implemented with a plurality of memory chips stacked through a through silicon via (TSV) (hereinafter denoted as a “through electrode”) like high bandwidth memory (HBM) or with a plurality of memory chips stacked through wire bonding.

With higher integration and higher performance, methods that detect a connection failure of through electrodes TSV through which a plurality of memory chips is stacked are required. A representative method that detects a connection failure of the through electrodes TSV may be performed through a scan operation (a through silicon via open short test) that turns on a PMOS transistor that is connected to a through electrode TSV of a memory chip disposed at the top layer, turns on an NMOS transistor that is connected to a through electrode TSV of a base chip that is disposed at the bottom layer, and then detects that the through electrode TSV is driven to a set logic level.

Such a scan operation (a through silicon via open short test) may be used to detect an open failure in which a through electrode TSV is disconnected, but has a problem in that it is difficult to detect a short failure in which through electrodes TSV are connected.

### SUMMARY

In an embodiment, a semiconductor device may include a base chip and a memory chip stacked with first, second, third, and fourth signal paths, each signal path extending through the memory chip into the base chip. The base chip and the memory chip may be configured to simultaneously drive the first signal path and the third signal path after the start of an even scan operation and may then simultaneously drive the second signal path and the fourth signal path after the start of an odd scan operation. The base chip may be configured to generate first, second, third, and fourth fail detection signals that detect a connection failure of the first, second, third, and fourth signal paths, respectively, based on a logic level at which the first, second, third, and fourth signal paths are driven.

In an embodiment, a semiconductor device may include a memory chip configured to simultaneously drive first and third signal paths through first and third PMOS transistors and configured to simultaneously drive second and fourth signal paths through second and fourth PMOS transistors. The semiconductor device may also include a base chip configured to simultaneously drive the first and third signal paths through first and third NMOS transistors, configured to simultaneously drive the second and fourth signal paths through second and fourth NMOS transistors, and configured to detect a connection failure of the first, second, third, and fourth signal paths by detecting logic levels at which the first, second, third, and fourth signal paths are driven.

### BRIEF DESCRIPTION OF THE DRAWINGS

FIG. 1 is a block diagram illustrating an embodiment of a semiconductor device.

FIG. 2 is a block diagram illustrating an embodiment of a base chip that is included in the semiconductor device illustrated in FIG. 1.

FIG. 3 is a circuit diagram illustrating an embodiment of a test signal generation circuit that is included in the base chip illustrated in FIG. 2.

FIG. 4 is a block diagram illustrating an embodiment of a logic test circuit that is included in the base chip illustrated in FIG. 2.

FIG. 5 is a diagram illustrating an embodiment of a first fail signal generation circuit that is included in the logic test circuit illustrated in FIG. 4.

FIG. 6 is a diagram illustrating an embodiment of a second fail signal generation circuit that is included in the logic test circuit illustrated in FIG. 4.

FIG. 7 is a diagram illustrating an embodiment of a fail detection signal generation circuit that is included in the logic test circuit illustrated in FIG. 4.

FIG. 8 is a block diagram illustrating an embodiment of a fourth memory chip that is included in the semiconductor device illustrated in FIG. 1.

FIG. 9 is a block diagram illustrating an embodiment of a test control circuit that is included in the fourth memory chip illustrated in FIG. 8.

FIG. 10 is a circuit diagram illustrating an embodiment of a first path driving circuit that is included in the test control circuit illustrated in FIG. 9.

FIG. 11 is a circuit diagram illustrating an embodiment of a second path driving circuit that is included in the test control circuit illustrated in FIG. 9.

FIGS. 12 to 17 are diagrams illustrating an even scan operation and odd scan operation of a semiconductor device according to an embodiment of the present disclosure.

FIG. 18 is a diagram illustrating an arrangement of a plurality of signal paths that are included in a semiconductor device according to an embodiment of the present disclosure.

FIG. 19 is a diagram illustrating an embodiment of an electronic system to which a semiconductor device according to an embodiment of the present disclosure is applied.

### DETAILED DESCRIPTION

In the descriptions of the following embodiments, the term “preset” indicates that the numerical value of a parameter is previously decided, when the parameter is used in a process or algorithm. According to an embodiment, the numerical value of the parameter may be set when the process or algorithm is started or while the process or algorithm is performed.

Terms such as “first” and “second,” which are used to distinguish among various components, are not limited by the components. For example, a first component may be referred to as a second component, and vice versa. Terms such as “first” and “second” are not intended to indicate a number or order of components.

When one component is referred to as being “coupled” or “connected” to another component, the components may be directly coupled or connected to each other or coupled or connected to each other through another component interposed therebetween. In contrast, when one component is referred to as being “directly coupled” or “directly connected” to another component, the components are directly coupled or connected to each other without another component interposed therebetween.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage may correspond to a signal having a “logic low level.” According to an embodiment, a “logic high level” may be set to a voltage higher than a “logic low level.” According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

Hereafter, the present disclosure will be described in more detail through embodiments. The embodiments are only used to exemplify the present disclosure, and the scope of the present disclosure is not limited by the embodiments.

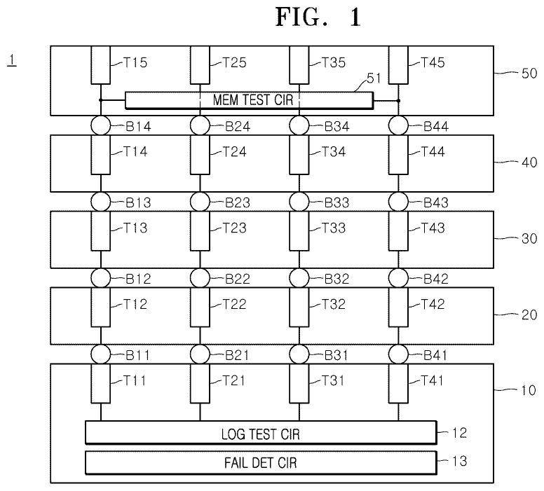

As illustrated in FIG. 1, a semiconductor device 1 according to an embodiment of the present disclosure includes a base chip 10, a first memory chip 20, a second memory chip 30, a third memory chip 40, and a fourth memory chip 50.

The base chip 10 is electrically connected to first, second, third, and fourth signal paths. The first signal path may be implemented with electrical connections of through electrodes T11, T12, T13, T14, and T15 and bumps B11, B12, B13, and B14. The second signal path may be implemented with electrical connections of through electrodes T21, T22, T23, T24, and T25 and bumps B21, B22,

B23, and B24. The third signal path may be implemented with electrical connections of through electrodes T31, T32, T33, T34, and T35 and bumps B31, B32, B33, and B34. The fourth signal path may be implemented with electrical connections of through electrodes T41, T42, T43, T44, and T45 and bumps B41, B42, B43, and B44. The through electrodes T11, T12, T13, T14, T15, T21, T22, T23, T24, T25, T31, T32, T33, T34, T35, T41, T42, T43, T44, and T45 may each be implemented in a cylindrical form in which each through electrode is implemented using a conductive material to be vertically stacked through a corresponding chip, among the base chip 10, the first memory chip 20, the second memory chip 30, the third memory chip 40, and the fourth memory chip 50. The bumps B11, B12, B13, B14, B21, B22, B23, B24, B31, B32, B33, B34, B41, B42, B43, and B44 may each be implemented in a ball form in which each bump is implemented using a conductive material to be directly connected to a circuit board.

The through electrodes T11, T12, T13, T14, and T15 of the first signal path and the through electrodes T31, T32, T33, T34, and T35 of the third signal path are set as even through electrodes, for example. The through electrodes T21, T22, T23, T24, and T25 of the second signal path and the through electrodes T41, T42, T43, T44, and T45 of the fourth signal path are set as odd through electrodes, for example. The through electrodes T11, T12, T13, T14, and T15 that form the first signal path and the through electrodes T21, T22, T23, T24, and T25 that form the second signal path are disposed to be consecutive to each other. The through electrodes T21, T22, T23, T24, and T25 that form the second signal path and the through electrodes T31, T32, T33, T34, and T35 that form the third signal path are disposed to be consecutive to each other. The through electrodes T31, T32, T33, T34, and T35 that form the third signal path and the through electrodes T41, T42, T43, T44, and T45 that form the fourth signal path are disposed to be consecutive to each other. The through electrodes T11, T12, T13, T14, and T15 of the first signal path and the through electrodes T31, T32, T33, T34, and T35 of the third signal path are not disposed to be consecutive to each other through the through electrodes T21, T22, T23, T24, and T25 of the second signal path. The through electrodes T21, T22, T23, T24, and T25 of the second signal path and the through electrodes T41, T42, T43, T44, and T45 of the fourth signal path are not disposed to be consecutive to each other through the through electrodes T31, T32, T33, T34, and T35 that form the third signal path. Each of the first, second, third, and fourth signal paths includes the five through electrodes, but may include various numbers of through electrodes according to different embodiments.

In an embodiment, the base chip 10 includes the through electrodes T11, T21, T31, and T41, a logic test circuit (LOG TEST CIR) 12, and a fail detection circuit (FAIL DET CIR) 13.

The through electrode T11 is electrically connected to the bump B11. The through electrode T21 is electrically connected to the bump B21. The through electrode T31 is electrically connected to the bump B31. The through electrode T41 is electrically connected to the bump B41.

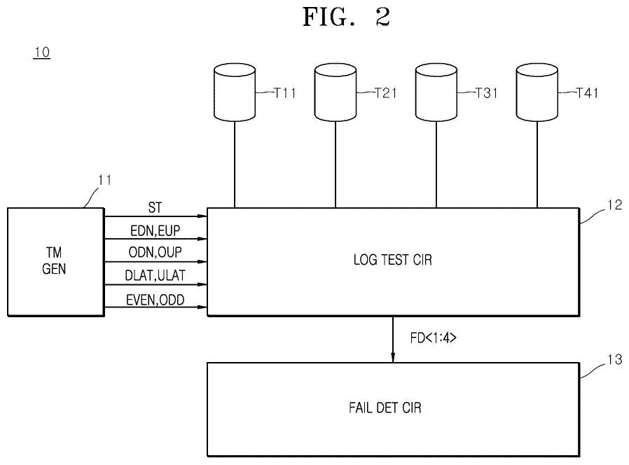

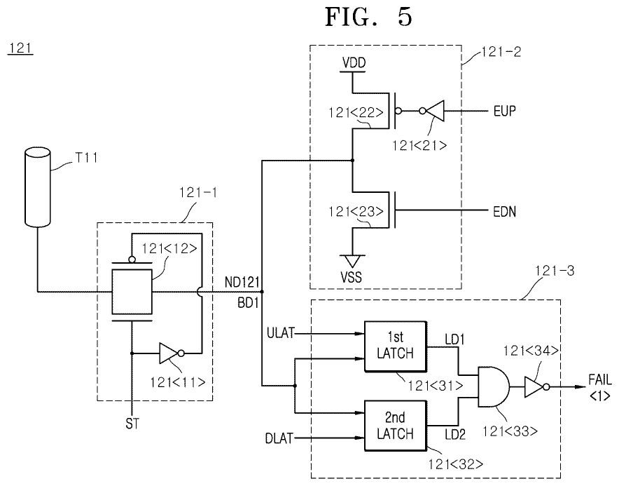

The logic test circuit 12 may drive the through electrodes T11, T21, T31, and T41 through any one of a PMOS transistor and an NMOS transistor after the start of an even scan operation and an odd scan operation. The logic test circuit 12 may drive the through electrodes T11, T21, T31, and T41 using a power source voltage VDD in FIG. 5, for example, through the PMOS transistor after the start of an even scan operation and an odd scan operation. The logic test circuit 12 may drive the through electrodes T11, T21, T31, and T41 using a ground voltage VSS in FIG. 5, for example, through the NMOS transistor after the start of an even scan operation and an odd scan operation. The logic test circuit 12 generates fail detection signals, for example, FD<1:4> in FIG. 2, by detecting the logic levels of the through electrodes T11, T21, T31, and T41, after the start of an even scan operation and an odd scan operation.

The fail detection circuit 13 detects a connection failure of

the first, second, third, and fourth signal paths based on the fail detection signals, for example, FD<1:4> in FIG. 2, after the start of an even scan operation and an odd scan operation.

The first memory chip 20 is electrically connected to the bumps B11, B21, B31, and B41 and stacked on or over the base chip 10, for example.

In an embodiment, the first memory chip 20 includes the through electrodes T12, T22, T32, and T42.

The through electrode T12 is electrically connected between the bump B11 and the bump B12. The through electrode T22 is electrically connected between the bump B21 and the bump B22. The through electrode T32 is electrically connected between the bump B31 and the bump B32. The through electrode T42 is electrically connected between the bump B41 and the bump B42.

The second memory chip 30 is electrically connected to the bumps B12, B22, B32, and B42 and stacked on or over the first memory chip 20, for example.

In an embodiment, the second memory chip 30 includes the through electrodes T13, T23, T33, and T43.

The through electrode T13 is electrically connected between the bump B12 and the bump B13. The through electrode T23 is electrically connected between the bump B22 and the bump B23. The through electrode T33 is electrically connected between the bump B32 and the bump B33. The through electrode T43 is electrically connected between the bump B42 and the bump B43.

The third memory chip 40 is electrically connected to the bumps B13, B23, B33, and B43 and stacked on or over the second memory chip 30, for example.

In an embodiment, the third memory chip 40 includes the through electrodes T14, T24, T34, and T44.

The through electrode T14 is electrically connected between the bump B13 and the bump B14. The through electrode T24 is electrically connected between the bump B23 and the bump B24. The through electrode T34 is electrically connected between the bump B33 and the bump B34. The through electrode T44 is electrically connected between the bump B43 and the bump B44.

The fourth memory chip 50 is electrically connected to the bumps B14, B24, B34, and B44 and stacked on or over the third memory chip 40, for example.

In an embodiment, the fourth memory chip 50 includes the through electrodes T15, T25, T35, and T45 and a memory test circuit (MEM TEST CIR) 51.

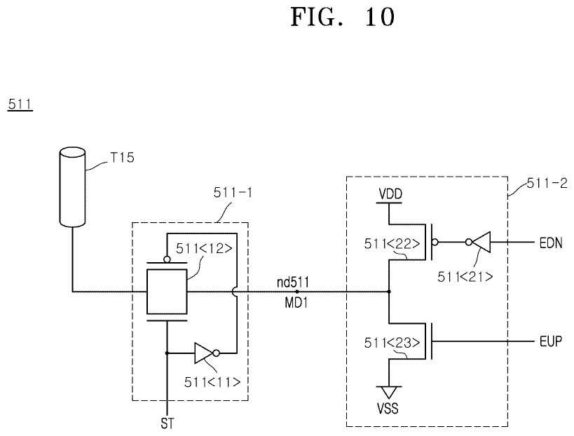

The memory test circuit 51 may drive the through electrodes T15, T25, T35, and T45 through any one of a PMOS transistor and a NMOS transistor after the start of an even scan operation and an odd scan operation. The memory test circuit 51 may drive the through electrodes T15, T25, T35, and T45 using the power source voltage VDD in FIG. 10, for example, through the PMOS transistor after the start of an even scan operation and an odd scan operation. The memory test circuit 51 may drive the through electrodes T15, T25, T35, and T45 using the ground voltage VSS in FIG. 10, for example, through the NMOS transistor after the start of an even scan operation and an odd scan operation.

FIG. 1 illustrates that the first, second, third, and fourth memory chips 20, 30, 40, and 50 are stacked on or over the base chip 10, but various numbers of memory chips, such as 8 or 16 chips, may be stacked on or over the base chip 10 according to an embodiment. The semiconductor device 1 illustrated in FIG. 1 is

implemented with the base chip 10 and the first, second, third, and fourth memory chips 20 to 50 stacked through through electrodes (through silicon vias (TSVs)) like high bandwidth memory (HBM), but may be implemented with a plurality of memory chips stacked through wire bonding according to an embodiment. The wire bonding may be set as a signal path for signals that are input and output in the base chip 10 from and to the first, second, third, and fourth memory chips 20 to 50 according to an embodiment.

FIG. 2 is a block diagram illustrating an embodiment of the base chip 10 that is included in the semiconductor device illustrated in FIG. 1. In an embodiment, the base chip 10 includes a test signal generation circuit (TM GEN) 11, a logic test circuit (LOG TEST CIR) 12, and a fail detection circuit (FAIL DET CIR) 13.

The test signal generation circuit 11 generates a switch signal ST that is enabled during an even scan operation and an odd scan operation. The test signal generation circuit 11 generates an even down signal EDN and an even up signal EUP that are selectively enabled during an even scan operation. The test signal generation circuit 11 generates an even test signal EVEN that is enabled during an even scan operation. The test signal generation circuit 11 generates an odd down signal ODN and an odd up signal OUP that are selectively enabled during an odd scan operation. The test signal generation circuit 11 generates an odd test signal ODD that is enabled during an odd scan operation. The test signal generation circuit 11 generates a down latch signal DLAT and an up latch signal ULAT that are enabled during an even scan operation and an odd scan operation.

The logic test circuit 12 is electrically connected to the through electrodes T11, T21, T31, and T41, for example. After the start of an even scan operation and an odd scan operation, the logic test circuit 12 drives the through electrodes T11, T21, T31, and T41 through any one of a PMOS transistor and an NMOS transistor. After the start of an even scan operation, the logic test circuit 12 drives the through electrodes T11, T21, T31, and T41 through any one of a PMOS transistor and an NMOS transistor, based on the switch signal ST, the even down signal EDN, and the even up signal EUP. After the start of an even scan operation, the logic test circuit 12 latches the logic levels of the through electrodes T11, T21, T31, and T41 based on the down latch signal DLAT and the up latch signal ULAT. The logic test circuit 12 generates first, second, third, and fourth fail detection signals FD<1:4> by detecting the logic levels of the through electrodes T11, T21, T31, and T41 that are latched after the start of an even scan operation. After the start of an odd scan operation, the logic test circuit 12 drives the through electrodes T11, T21, T31, and T41 through any one of the PMOS transistor and the NMOS transistor, based on the switch signal ST, the odd down signal ODN, and the odd up signal OUP. After the start of an odd scan operation, the logic test circuit 12 latches the logic levels of the through electrodes T11, T21, T31, and T41 based on the down latch signal DLAT and the up latch signal ULAT. The logic test circuit 12 generates the first, second, third, and fourth fail detection signals FD<1:4> by detecting the logic levels of the through electrodes T11, T21, T31, and T41 that are latched after the start of an odd scan operation. After the start of an even scan operation and an odd scan operation, the logic test circuit 12 generates the first, second, third, and fourth fail detection signals FD<1:4> by detecting the logic levels of the through electrodes T11, T21, T31, and T41.

After the start of an even scan operation and an odd scan operation, the fail detection circuit 13 detects a connection failure of the through electrodes T11, T21, T31, and T41 based on the first, second, third, and fourth fail detection signals FD<1:4>. After the start of an even scan operation and an odd scan operation, the fail detection circuit 13 detects an open failure in which the through electrodes T11, T21, T31, and T41 are disconnected, by detecting the logic levels of the first, second, third, and fourth fail detection signals FD<1:4>. After the start of an even scan operation and an odd scan operation, the fail detection circuit 13 detects a short failure in which the through electrodes T11, T21, T31, and T41 are connected, by detecting the logic levels of the first, second, third, and fourth fail detection signals FD<1:4>.

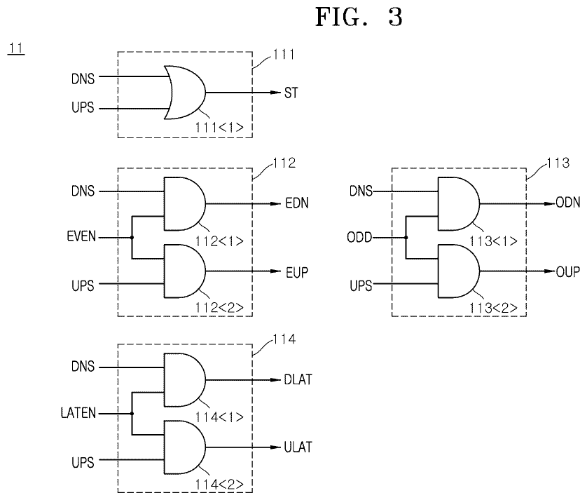

FIG. 3 is a circuit diagram illustrating an embodiment of the test signal generation circuit 11 that is included in the base chip 10 illustrated in FIG. 2. In an embodiment, the test signal generation circuit 11 includes a switch signal generation circuit 111, an even test signal generation circuit 112, an odd test signal generation circuit 113, and a latch signal generation circuit 114.

In an embodiment, the switch signal generation circuit 111 includes an OR gate 111<1>. The switch signal generation circuit 111 generates the switch signal ST, based on a down scan signal DNS and an up scan signal UPS. After the start of a down scan operation, the switch signal generation circuit 111 generates the switch signal ST that is enabled to a logic high level when the down scan signal DNS having a logic high level is input. After the start of an up scan operation, the switch signal generation circuit 111 generates the switch signal ST that is enabled to a logic high level when the up scan signal UPS having a logic high level is input. The down scan operation may be set as an operation that detects a connection failure of the through electrodes T11, T21, T31, and T41 and the through electrodes T14, T24, T34, and T44 by driving, through a PMOS transistor, the through electrodes T14, T24, T34, and T44 that are connected to the fourth memory chip 50, and driving, through an NMOS transistor, the through electrodes T11, T21, T31, and T41 that are connected to the base chip 10. The up scan operation may be set as an operation that detects a connection failure of the through electrodes T11, T21, T31, and T41 and the through electrodes T14, T24, T34, and T44 by driving, through an NMOS transistor, the through electrodes T14, T24, T34, and T44 that are connected to the fourth memory chip 50, and driving, through a PMOS transistor, the through electrodes T11, T21, T31, and T41 that are connected to the base chip 10. The down scan signal DNS may be set as a signal that is enabled to a logic high level after the start of a down scan operation. The up scan signal UPS may be set as a signal that is enabled to a logic high level after the start of an up scan operation.

In an embodiment, the even test signal generation circuit 112 includes AND gates 112<1> and 112<2>. The even test signal generation circuit 112 generates the even down signal EDN that is enabled to a logic high level, when an even test signal EVEN having a logic high level is input and a down scan signal DNS having a logic high level is input, during an even scan operation. The even test signal generation circuit 112 generates the even up signal EUP that is enabled to a logic high level, when the even test signal EVEN having a logic high level is input and an up scan signal UPS having a logic high level is input, during an even scan operation. The even test signal generation circuit 112 generates the even down signal EDN that is disabled to a logic low level, when the even test signal EVEN having a logic low level is input, during an odd scan operation. The even test signal generation circuit 112 generates the even up signal EUP that is disabled to a logic low level, when the even test signal EVEN having a logic low level is input, during an odd scan operation. The even test signal EVEN may be set as a signal that is enabled to a logic high level after the start of an even scan operation.

In an embodiment, the odd test signal generation circuit 113 includes AND gates 113<1> and 113<2>. The odd test signal generation circuit 113 generates the odd down signal ODN that is enabled to a logic high level, when the odd test signal ODD having a logic high level is input and the down scan signal DNS having a logic high level is input, during an odd scan operation. The odd test signal generation circuit 113 generates the odd up signal OUP that is enabled to a logic high level, when the odd test signal ODD having a logic high level is input and the up scan signal UPS having a logic high level is input, during an odd scan operation. The odd test signal generation circuit 113 generates the odd down signal ODN that is disabled to a logic low level, when the odd test signal ODD having a logic low level is input, during an even scan operation. The odd test signal generation circuit 113 generates the odd up signal OUP that is disabled to a logic low level, when the odd test signal ODD having a logic low level is input, during an even scan operation. The odd test signal ODD may be set as a signal that is enabled to a logic high level after the start of an odd scan operation.

In an embodiment, the latch signal generation circuit 114 includes AND gates 114<1> and 114<2>. The latch signal generation circuit 114 generates the down latch signal DLAT that is enabled to a logic high level, when a latch enable signal LATEN having a logic high level is input and the down scan signal DNS having a logic high level is input, during an even scan operation and an odd scan operation. The latch signal generation circuit 114 generates the up latch signal ULAT that is enabled to a logic high level, when the latch enable signal LATEN having a logic high level is input and the up scan signal UPS having a logic high level is input, during an even scan operation and an odd scan operation. The latch signal generation circuit 114 generates the down latch signal DLAT that is disabled to a logic low level when the latch enable signal LATEN having a logic low level is input, after an even scan operation and an odd scan operation. The latch signal generation circuit 114 generates the up latch signal ULAT that is disabled to a logic low level when the latch enable signal LATEN having a logic low level is input, after an even scan operation and an odd scan operation. The latch enable signal LATEN may be set as a signal that is enabled to a logic high level after the start of an even scan operation and an odd scan operation.

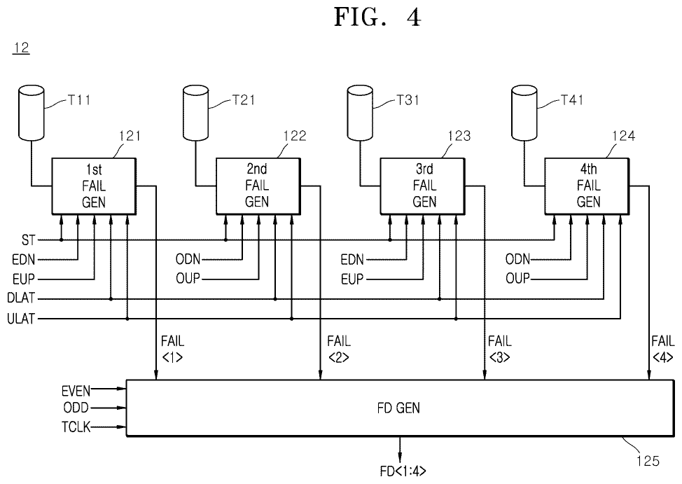

FIG. 4 is a block diagram illustrating an embodiment of the logic test circuit 12 that is included in the base chip 10 illustrated in

FIG. 2. In an embodiment, the logic test circuit 12 includes a first fail signal generation circuit (1^{st} FAIL GEN) 121, a second fail signal generation circuit (2^{nd} FAIL GEN) 122, a third fail signal generation circuit (3^{rd} FAIL GEN) 123, a fourth fail signal generation circuit (4^{th} FAIL GEN) 124, and a fail detection signal generation circuit (FD GEN) 125.

The first fail signal generation circuit 121 is electrically connected to the through electrode T11 that forms the first signal path. The first fail signal generation circuit 121 generates a first fail signal FAIL<1>, based on the switch signal ST, the even down signal EDN, the even up signal EUP, the down latch signal DLAT, and the up latch signal ULAT. The first fail signal generation circuit 121 drives the through electrode T11 toward an NMOS transistor 121<23> in FIG. 5, for example, when the switch signal ST is enabled and the even down signal EDN is enabled. The first fail signal generation circuit 121 latches the logic level of the through electrode T11 that is driven through the NMOS transistor 121<23> in FIG. 5, when the down latch signal DLAT is enabled. The first fail signal generation circuit 121 drives the through electrode T11 through a PMOS transistor 121<22> in FIG. 5, for example, when the switch signal ST is enabled and the even up signal

EUP is enabled. The first fail signal generation circuit 121 latches the logic level of the through electrode T11 that is driven through the PMOS transistor 121<22> in FIG. 5, for example, when the up latch signal ULAT is enabled. The first fail signal generation circuit 121 generates the first fail signal FAIL<1>, based on the logic level of the through electrode T11 that is driven through the NMOS transistor 121<23> in FIG. 5, for example, and the logic level of the through electrode T11 that is driven through the PMOS transistor 121<22> in FIG. 5, for example.

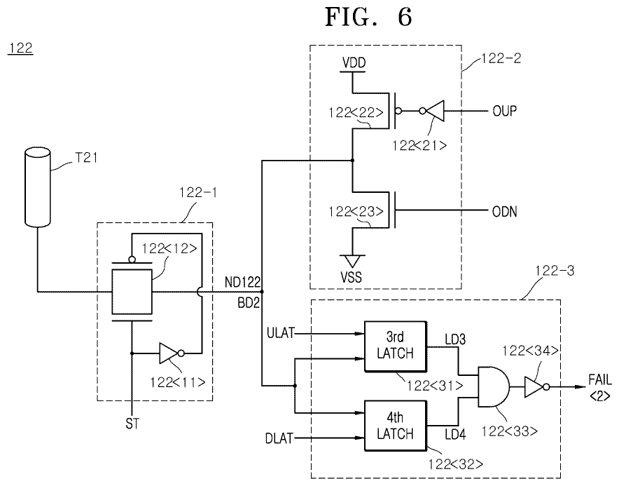

The second fail signal generation circuit 122 is electrically connected to the through electrode T21 that forms the second signal path. The second fail signal generation circuit 122 generates a second fail signal FAIL<2>, based on the switch signal ST, the odd down signal ODN, the odd up signal OUP, the down latch signal DLAT, and the up latch signal ULAT. The second fail signal generation circuit 122 drives the through electrode T21 through an NMOS transistor 122<23> in FIG. 6, for example, when the switch signal ST is enabled and the odd down signal ODN is enabled. The second fail signal generation circuit 122 latches the logic level of the through electrode T21 that is driven through the NMOS transistor 122<23> in FIG. 6, for example, when the down latch signal DLAT is enabled. The second fail signal generation circuit 122 drives the through electrode T21 through a PMOS transistor 122<22> in FIG. 6, for example, when the switch signal ST is enabled and the odd up signal OUP is enabled. The second fail signal generation circuit 122 latches the logic level of the through electrode T21 that is driven through the PMOS transistor 122<22> in FIG. 6, for example, when the up latch signal ULAT is enabled. The second fail signal generation circuit 122 generates the second fail signal FAIL<2>, based on the logic level of the through electrode T21 that is driven through the NMOS transistor 122<23> in FIG. 6, for example, and the logic level of the through electrode T21 that is driven through the PMOS transistor 122<22> in FIG. 6, for example.

The third fail signal generation circuit 123 is electrically connected to the through electrode T31 that forms the third signal path. The third fail signal generation circuit 123 generates a third fail signal FAIL<3>, based on the switch signal ST, the even down signal EDN, the even up signal EUP, the down latch signal DLAT, and the up latch signal ULAT. The third fail signal generation circuit 123 drives the through electrode T31 through the NMOS transistor (not illustrated) of the third fail signal generation circuit 123 when the switch signal ST is enabled and the even down signal EDN is enabled. The third fail signal generation circuit 123 latches the logic level of the through electrode T31 that is driven through the NMOS transistor (not illustrated) of the third fail signal generation circuit 123, when the down latch signal DLAT is enabled. The third fail signal generation circuit 123 drives the through electrode T31 through the PMOS transistor (not illustrated) of the third fail signal generation circuit 123 when the switch signal ST is enabled and the even up signal EUP is enabled. The third fail signal generation circuit 123 latches the logic level of the through electrode T31 that is driven through the PMOS transistor (not illustrated) of the third fail signal generation circuit 123, when the up latch signal ULAT is enabled. The third fail signal generation circuit 123 generates the third fail signal FAIL<3>, based on the logic level of the through electrode T31 that is driven through the NMOS transistor (not illustrated) of the third fail signal generation circuit 123 and the logic level of the through electrode T31 that is driven through the PMOS transistor (not illustrated) of the third fail signal generation circuit 123.

The fourth fail signal generation circuit 124 is electrically connected to the through electrode T41 that forms the fourth signal path. The fourth fail signal generation circuit 124 generates a fourth fail signal FAIL<4>, based on the switch signal ST, the odd down signal ODN, the odd up signal OUP, the down latch signal DLAT, and the up latch signal ULAT. The fourth fail signal generation circuit 124 drives the through electrode T41 through the NMOS transistor (not illustrated) of the fourth fail signal generation circuit 124 when the switch signal ST is enabled and the odd down signal ODN is enabled. The fourth fail signal generation circuit 124 latches the logic level of the through electrode T41 that is driven through the NMOS transistor (not illustrated) of the fourth fail signal generation circuit 124, when the down latch signal DLAT is enabled. The fourth fail signal generation circuit 124 drives the through electrode T41 through the PMOS transistor (not illustrated) of the fourth fail signal generation circuit 124 when the switch signal ST is enabled and the odd up signal OUP is enabled. The fourth fail signal generation circuit 124 latches the logic level of the through electrode T41 that is driven through the PMOS transistor (not illustrated) of the fourth fail signal generation circuit 124, when the up latch signal ULAT is enabled. The fourth fail signal generation circuit 124 generates the fourth fail signal FAIL<4>, based on the logic level of the through electrode T41 that is driven through the NMOS transistor (not illustrated) of the fourth fail signal generation circuit 124 and the logic level of the through electrode T41 that is driven through the PMOS transistor (not illustrated) of the fourth fail signal generation circuit 124.

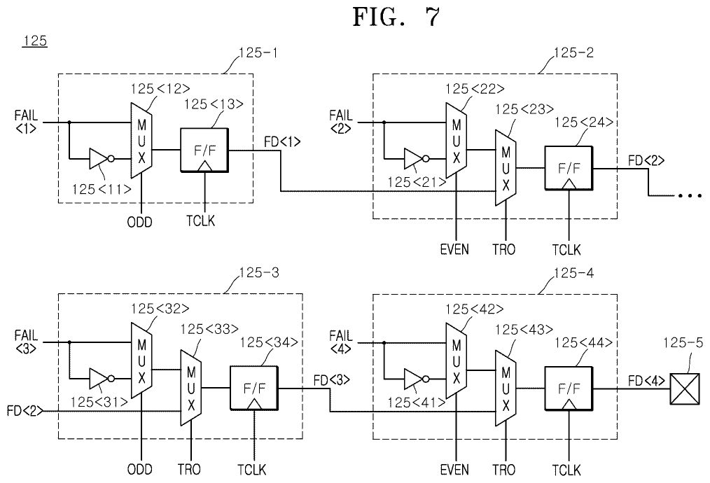

The fail detection signal generation circuit 125 generates the first, second, third, and fourth fail detection signals FD<1:4>, based on the even test signal EVEN, the odd test signal ODD, and the first, second, third, and fourth fail signals FAIL<1:4>, in synchronization with a test clock TCLK. The fail detection signal generation circuit 125 outputs the first, second, third, and fourth fail detection signals FD<1:4> by serializing the first, second, third, and fourth fail signals FAIL<1:4> based on the even test signal EVEN and the odd test signal ODD, in synchronization with the test clock TCLK. The fail detection signal generation circuit 125 outputs the first, second, third, and fourth fail detection signals FD<1:4> through an output pad, for example, 125-5 in FIG. 7 by serializing the first, second, third, and fourth fail signals FAIL<1:4> based on the even test signal EVEN and the odd test signal ODD, in synchronization with the test clock TCLK.

FIG. 5 is a diagram illustrating an embodiment of the first fail signal generation circuit 121 that is included in the logic test circuit 12 illustrated in FIG. 4. In an embodiment, the first fail signal generation circuit 121 includes a first switch circuit 121-1, a first driving circuit 121-2, and a first storage circuit 121-3.

In an embodiment, the first switch circuit 121-1 includes an inverter 121<11> and a transfer gate 121<12>. The first switch circuit 121-1 connects the through electrode T11 and a node ND121 when the switch signal ST is enabled to a logic high level.

In an embodiment, the first driving circuit 121-2 includes an inverter 121<21>, a PMOS transistor 121<22>, and the NMOS transistor 121<23>. The inverter 121<21> outputs the even up signal EUP by inverting the even up signal EUP. For example, the even up signal EUP output from the inverter 121<21> represents the inversion of the even up signal EUP input to the inverter 121<21>. The PMOS transistor 121<22> is connected between a power source voltage VDD and the node ND121, and generates first base data BD1 having a logic high level by driving the node ND121 to the voltage level of the power source voltage VDD when the output signal of the inverter 121<21> is at a logic low level. The NMOS transistor 121<23> is connected between the node ND121 and a ground voltage VSS, and generates the first base data BD1 having a logic low level by driving the node ND121 to the voltage level of the ground voltage VSS when the even down signal EDN is at a logic high level. For example, the PMOS transistor 121<22> of the first driving circuit 121-2 may be set to have a greater driving force than an NMOS transistor 511<23> of a first path driving circuit 511 in FIG. 10, for example. Accordingly, when a failure does not occur in the through electrodes T11, T12, T13, and T14 that form the first signal path, the first driving circuit 121-2 drives the through electrodes T11, T12, T13, and T14 to the voltage level of the power source voltage VDD, for example.

In an embodiment, the first storage circuit 121-3 includes a first latch (1^{st} LATCH) 121<31>, a second latch (2^{nd} LATCH) 121<32>, an AND gate 121<33>, and an inverter 121<34>.

The first latch 121<31> latches the first base data BD1 when the up latch signal ULAT is enabled to a logic high level. The first latch 121<31> outputs, as first latch data LD1, the first base data BD1 that have been latched.

The second latch 121<32> latches the first base data BD1 when the down latch signal DLAT is enabled to a logic high level. The second latch 121<32> outputs, as second latch data LD2, the first base data BD1 that have been latched.

The AND gate 121<33> and the inverter 121<34>generates the first fail signal FAIL<1> based on the logic levels of the first latch data LD1 and the second latch data LD2. The AND gate 121<33> and the inverter 121<34> generate the first fail signal FAIL<1> having a logic low level when the first latch data LD1 is at a logic high level and the second latch data LD2 is at a logic high level. The AND gate 121<33> and the inverter 121<34> generates the first fail signal FAIL<1> having a logic high level when at least any one of the first latch data LD1 and the second latch data LD2 is at a logic low level.

The third fail signal generation circuit 123 illustrated in FIG. 4 is electrically connected to the through electrode T31 and merely generates the third fail signal FAIL<3>, and is implemented with the same circuit as the first fail signal generation circuit 121 illustrated in

FIG. 5 and performs the same operation as the first fail signal generation circuit 121 and thus a detailed description thereof is omitted.

FIG. 6 is a diagram illustrating an embodiment of the second fail signal generation circuit 122 that is included in the logic test circuit 12 illustrated in FIG. 4. In an embodiment, the second fail signal generation circuit 122 includes a second switch circuit 122-1, a second driving circuit 122-2, and a second storage circuit 122-3.

In an embodiment, the second switch circuit 122-1 includes an inverter 122<11> and a transfer gate 122<12>. The second switch circuit 122-1 connects the through electrode T21 and a node ND122 when the switch signal ST is enabled to a logic high level.

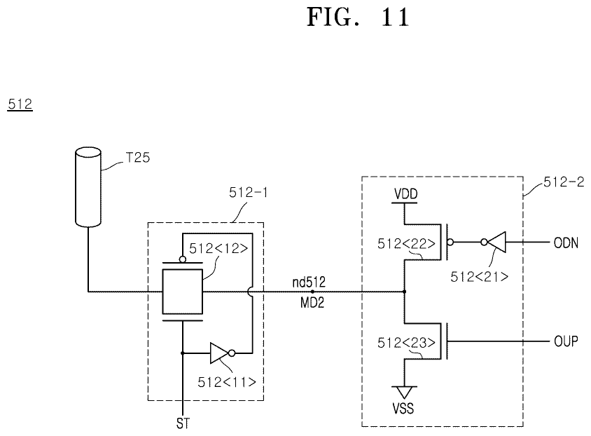

In an embodiment, the second driving circuit 122-2 includes an inverter 122<21>, a PMOS transistor 122<22>, and an NMOS transistor 122<23>. The inverter 122<21> outputs the odd up signal OUP by inverting the odd up signal OUP. For example, the odd up signal OUP output from the inverter 122<21> represents the inversion of the odd up signal OUP input to the inverter 122<21>. The PMOS transistor 122<22> is connected between the power source voltage VDD and the node ND122, and generates second base data BD2 having a logic high level by driving the node ND122 to the voltage level of the power source voltage VDD when the output signal of the inverter 122<21> is at a logic low level. The NMOS transistor 122<23> is connected between the node ND122 and the ground voltage VSS, and generates the second base data BD2 having a logic low level by driving the node ND122 to the voltage level of the ground voltage VSS when the odd down signal ODN is at a logic high level. The PMOS transistor 122<22> of the second driving circuit 122-2 may be set to have a greater driving force than an NMOS transistor 512<23> of a second path driving circuit 512 in FIG. 11, for example. Accordingly, when a failure does not occur in the through electrodes T21, T22, T23, and T24 that form the second signal path, the second driving circuit 122-2 drives the through electrodes T21, T22, T23, and T24 to the voltage level of the power source voltage VDD.

In an embodiment, the second storage circuit 122-3 includes a third latch (3r LATCH) 122<31>, a fourth latch (4^{th} LATCH) 122<32>, an AND gate 122<33>, and an inverter 122<34>.

The third latch 122<31> latches the second base data BD2 when the up latch signal ULAT is enabled to a logic high level. The third latch 122<31> outputs, as third latch data LD3, the second base data BD2 that have been latched.

The fourth latch 122<32> latches the second base data BD2 when the down latch signal DLAT is enabled to a logic high level. The fourth latch 122<32> outputs, as fourth latch data LD4, the second base data BD2 that have been latched.

The AND gate 122<33> and the inverter 122<34>generate the second fail signal FAIL<2> based on the logic levels of the third latch data LD3 and the fourth latch data LD4. The AND gate 122<33> and the inverter 122<34> generate the second fail signal FAIL<2> having a logic low level when the third latch data LD3 is at a logic high level and the fourth latch data LD4 is at a logic high level. The AND gate 122<33> and the inverter 122<34> generate the second fail signal FAIL<2> having a logic high level when at least any one of the third latch data LD3 and the fourth latch data LD4 is at a logic low level.

The fourth fail signal generation circuit 124 illustrated in FIG. 4 is electrically connected to the through electrode T41 and merely generates the fourth fail signal FAIL<4>, and is implemented with the same circuit as the second fail signal generation circuit 122 illustrated in FIG. 6 and performs the same operation as the second fail signal generation circuit 122 and thus a detailed description thereof is omitted.

FIG. 7 is a diagram illustrating an embodiment of the fail detection signal generation circuit 125 that is included in the logic test circuit 12 illustrated in FIG. 4. In an embodiment, the fail detection signal generation circuit 125 includes a first fail detection signal generation circuit 125-1, a second fail detection signal generation circuit 125-2, a third fail detection signal generation circuit 125-3, and a fourth fail detection signal generation circuit 125-4.

In an embodiment, the first fail detection signal generation circuit 125-1 includes an inverter 125<11>, a multiplexer (MUX) 125<12>, and a flip-flop (F/F) 125<13>. The inverter 125<11> outputs the first fail signal FAIL<1> by inverting the first fail signal FAIL<1>. For example, the first fail signal FAIL<1> output from the inverter 125<11> represents the inversion of the first fail signal FAIL<1> input to the inverter 125<11>. The multiplexer 125<12> receives the first fail signal FAIL<1> when the odd test signal ODD is disabled to a logic low level and outputs the first fail signal FAIL<1>. The multiplexer 125<12> receives the output signal of the inverter 125<11> when the odd test signal ODD is enabled to a logic high level, and outputs the output signal of the inverter 125<11>. The flip-flop 125<13> outputs the output signal of the multiplexer 125<12> as the first fail detection signal FD<1> when the level of the test clock TCLK transitions from a logic low level to a logic high level. The first fail detection signal generation circuit 125-1 generates the first fail detection signal FD<1> by non-inverting the first fail signal FAIL<1> in synchronization with the test clock TCLK when the odd test signal ODD is disabled. The first fail detection signal generation circuit 125-1 generates the first fail detection signal FD<1> by inverting the first fail signal FAIL<1> in synchronization with the test clock TCLK when the odd test signal ODD is enabled.

In an embodiment, the second fail detection signal generation circuit 125-2 includes an inverter 125<21>, a multiplexer (MUX) 125<22>, a multiplexer (MUX) 125<23>, and a flip-flop (F/F) 125<24>. The inverter 125<21> outputs the second fail signal FAIL<2> by inverting the second fail signal FAIL<2>. For example, the second fail signal FAIL<2> output from the inverter 125<21>represents the inversion of the second fail signal FAIL<2> input to the inverter 125<21>. The multiplexer 125<22> receives the second fail signal FAIL<2> when the even test signal EVEN is disabled to a logic low level and outputs the second fail signal FAIL<2>. The multiplexer 125<22> receives the output signal of the inverter 125<21> when the even test signal EVEN is enabled to a logic high level, and outputs the output signal of the inverter 125<21>. The multiplexer 125<23> receives the output signal of the multiplexer 125<22> when a test read signal TRO is disabled to a logic low level, and outputs the output signal of the multiplexer 125<22>. The multiplexer 125<23> receives the first fail detection signal FD<1> when the test read signal TRO is enabled to a logic high level, and outputs the first fail detection signal FD<1>. The flip-flop 125<24> outputs the output signal of the multiplexer 125<23> as the second fail detection signal FD<2> when the level of the test clock TCLK transitions from a logic low level to a logic high level. The second fail detection signal generation circuit 125-2 generates the second fail detection signal FD<2> by non-inverting the second fail signal FAIL<2> in synchronization with the test clock TCLK when the even test signal EVEN is disabled and the test read signal TRO is disabled. The second fail detection signal generation circuit 125-2 generates the second fail detection signal FD<2> by inverting the second fail signal FAIL<2> in synchronization with the test clock TCLK when the even test signal EVEN is enabled and the test read signal TRO is disabled. The second fail detection signal generation circuit 125-2 generates the second fail detection signal FD<2> by non-inverting the first fail detection signal FD<1> in synchronization with the test clock TCLK when the test read signal TRO is enabled. The test read signal TRO may be set as a signal that is enabled to a logic high level to output the first, second, third, and fourth fail signals FAIL<1:4> as the first, second, third, and fourth fail detection signals FD<1:4>, respectively, through an output pad 125-5 by serializing the first, second, third, and fourth fail signals FAIL<1:4>.

In an embodiment, the third fail detection signal generation circuit 125-3 includes an inverter 125<31>, a multiplexer (MUX) 125<32>, a multiplexer (MUX) 125<33>, and a flip-flop (F/F) 125<34>. The inverter 125<31> outputs the third fail signal FAIL<3> by inverting the third fail signal FAIL<3>. For example, the third fail signal FAIL<3> output from the inverter 125<31> represents the inversion of the third fail signal FAIL<3> input to the inverter 125<31>. The multiplexer 125<32> receives the third fail signal FAIL<3> when the odd test signal ODD is disabled to a logic low level and outputs the third fail signal FAIL<3>. The multiplexer 125<32> receives the output signal of the inverter 125<31> when the odd test signal ODD is enabled to a logic high level, and outputs the output signal of the inverter 125<31>. The multiplexer 125<33> receives the output signal of the multiplexer 125<32> when the test read signal TRO is disabled to a logic low level, and outputs the output signal of the multiplexer 125<32>. The multiplexer 125<33> receives the second fail detection signal FD<2> when the test read signal TRO is enabled to a logic high level, and outputs the second fail detection signal FD<2>. The flip-flop 125<34> outputs the output signal of the multiplexer 125<33> as the third fail detection signal FD<3> when the level of the test clock TCLK transitions from a logic low level to a logic high level. The third fail detection signal generation circuit 125-3 generates the third fail detection signal FD<3> by non-inverting the third fail signal FAIL<3> in synchronization with the test clock TCLK when the odd test signal ODD is disabled and the test read signal TRO is disabled. The third fail detection signal generation circuit 125-3 generates the third fail detection signal FD<3> by inverting the third fail signal FAIL<3> in synchronization with the test clock TCLK when the odd test signal ODD is enabled and the test read signal TRO is disabled. The third fail detection signal generation circuit 125-3 generates the third fail detection signal FD<3> by non-inverting the second fail detection signal FD<2> in synchronization with the test clock TCLK when the test read signal TRO is enabled.

In an embodiment, the fourth fail detection signal generation circuit 125-4 includes an inverter 125<41>, a multiplexer (MUX) 125<42>, a multiplexer (MUX) 125<43>, and a flip-flop (F/F) 125<44>. The inverter 125<41> outputs the fourth fail signal FAIL<4> by inverting the fourth fail signal FAIL<4>. For example, the fourth fail signal FAIL<4> output from the inverter 125<41> represents the inversion of the fourth fail signal FAIL<4> input to the inverter 125<41>. The multiplexer 125<42> receives the fourth fail signal FAIL<4> when the even test signal EVEN is disabled to a logic low level, and outputs the fourth fail signal FAIL<4>. The multiplexer 125<42> receives the output signal of the inverter 125<41> when the even test signal EVEN is enabled to a logic high level, and outputs the output signal of the inverter 125<41>. The multiplexer 125<43> receives the output signal of the multiplexer 125<42> when the test read signal TRO is disabled to a logic low level, and outputs the output signal of the multiplexer 125<42>. The multiplexer 125<43> receives the third fail detection signal FD<3> when the test read signal TRO is enabled to a logic high level, and outputs the third fail detection signal FD<3>. The flip-flop 125<44> outputs the output signal of the multiplexer 125<43> as the fourth fail detection signal FD<4> when the level of the test clock TCLK transitions from a logic low level to a logic high level. The fourth fail detection signal generation circuit 125-4 generates the fourth fail detection signal FD<4> by non-inverting the fourth fail signal FAIL<4> in synchronization with the test clock TCLK when the even test signal EVEN is disabled and the test read signal TRO is disabled. The fourth fail detection signal generation circuit 125-4 generates the fourth fail detection signal FD<4> by inverting the fourth fail signal FAIL<4> in synchronization with the test clock TCLK when the even test signal EVEN is enabled and the test read signal TRO is disabled. The fourth fail detection signal generation circuit 125-4 generates the fourth fail detection signal FD<4> by non-inverting the third fail detection signal FD<3> in synchronization with the test clock TCLK when the test read signal TRO is enabled. The fourth fail detection signal generation circuit 125-4 outputs the fourth fail detection signal FD<4> through the output pad 125-5.

The fail detection signal generation circuit 125 outputs the fourth fail detection signal FD<4> that is generated from the fourth fail signal FAIL<4> through the output pad 125-5, and then outputs the fourth fail detection signal FD<4> that is generated from the third fail signal FAIL<3> through the output pad 125-5. The fail detection signal generation circuit 125 outputs the fourth fail detection signal FD<4> that is generated from the third fail signal FAIL<3> through the output pad 125-5, and then outputs the fourth fail detection signal FD<4> that is generated from the second fail signal FAIL<2> through the output pad 125-5. The fail detection signal generation circuit 125 outputs the fourth fail detection signal FD<4> that is generated from the second fail signal FAIL<2> through the output pad 125-5, and then outputs the fourth fail detection signal FD<4> that is generated from the first fail signal FAIL<1> through the output pad 125-5.

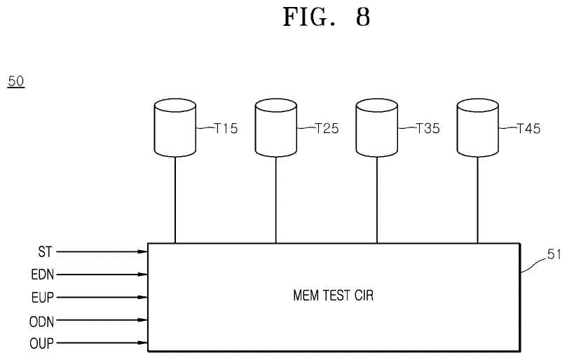

FIG. 8 is a block diagram illustrating an embodiment of the fourth memory chip 50 included the semiconductor device 1. In an embodiment, the fourth memory chip 50 includes a memory test circuit (MEM TEST CIR) 51.

The memory test circuit 51 receives the switch signal ST, the even down signal EDN, the even up signal EUP, the odd down signal ODN, the odd up signal OUP, the down latch signal DLAT, and the up latch signal ULAT from the base chip 10. The switch signal ST, the even down signal EDN, the even up signal EUP, the odd down signal ODN, the odd up signal OUP, the down latch signal DLAT, and the up latch signal ULAT may be input from the base chip 10 to the memory test circuit 51 through separate through electrodes except the through electrodes T11, T12, T13, T14, T21, T22, T23, T24, T31, T32, T33, T34, T41, T42, T43, and T44.

The memory test circuit 51 is electrically connected to the through electrodes T15, T25, T35, and T45. The memory test circuit 51 drives the through electrodes T15, T25, T35, and T45 through any one of a PMOS transistor and an NMOS transistor after the start of an even scan operation and an odd scan operation. The memory test circuit 51 drives the through electrodes T14, T24, T34, and T44 through any one of a PMOS transistor and an NMOS transistor, based on the switch signal ST, the even down signal EDN, and the even up signal EUP after the start of an even scan operation. The memory test circuit 51 drives the through electrodes T15 and T35 to the voltage level of the power source voltage VDD in FIG. 10, for example, through a PMOS transistor when the switch signal ST and the even down signal EDN are enabled after the start of an even scan operation. The memory test circuit 51 drives the through electrodes T15 and T35 to the voltage level of the ground voltage VSS in FIG. 10, for example, through an NMOS transistor when the switch signal ST and the even up signal EUP are enabled after the start of an even scan operation. The memory test circuit 51 drives the through electrodes T14, T24, T34, and T44 through any one of a PMOS transistor and an NMOS transistor, based on the switch signal ST, the odd down signal ODN, and the odd up signal OUP after the start of an odd scan operation. The memory test circuit 51 drives the through electrodes T25 and T45 to the voltage level of the power source voltage VDD in FIG. 11, for example, through a PMOS transistor when the switch signal ST and the odd down signal ODN are enabled after the start of an odd scan operation. The memory test circuit 51 drives the through electrodes T25 and T45 to the voltage level of the ground voltage VSS in FIG. 11, for example, through an NMOS transistor when the switch signal ST and the odd up signal OUP are enabled after the start of an odd scan operation.

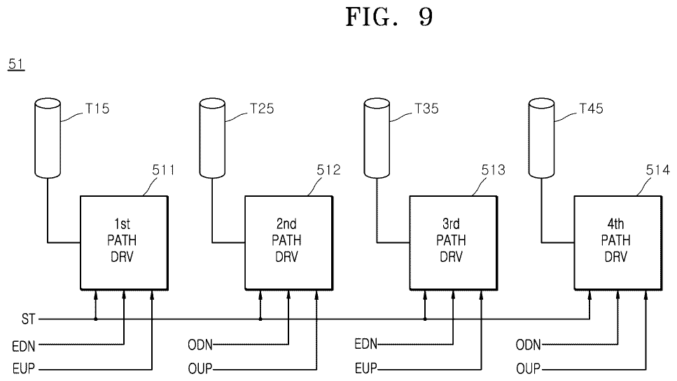

FIG. 9 is a block diagram illustrating an embodiment of the memory test circuit 51 that is included in the fourth memory chip 50 illustrated in FIGS. 1 and 8. In an embodiment, the memory test circuit 51 includes a first path driving circuit (1^{st} PATH DRV) 511, a second path driving circuit (2^{nd} PATH DRV) 512, a third path driving circuit (3^{rd} PATH DRV) 513, and a fourth path driving circuit (4^{th} PATH DRV) 514.

The first path driving circuit 511 is electrically connected to the through electrode T15 that forms the first signal path. The first path driving circuit 511 drives the through electrode T15, based on the switch signal ST, the even down signal EDN, and the even up signal

EUP. The first path driving circuit 511 drives the through electrode T15 through a PMOS transistor 511<22> in FIG. 10, for example, when the switch signal ST is enabled and the even down signal EDN is enabled. The first fail signal generation circuit 121 drives the through electrode T15 through an NMOS transistor 511<23> in FIG. 10, for example, when the switch signal ST is enabled and the even up signal EUP is enabled.

The second path driving circuit 512 is electrically connected to the through electrode T25 that forms the second signal path. The second path driving circuit 512 drives the through electrode T25, based on the switch signal ST, the odd down signal ODN, and the odd up signal OUP. The second path driving circuit 512 drives the through electrode T25 through a PMOS transistor 512<22> in FIG. 11, for example, when the switch signal ST is enabled and the odd down signal ODN is enabled. The second path driving circuit 512 drives the through electrode T25 through an NMOS transistor 512<23> in FIG. 11, for example, when the switch signal ST is enabled and the odd up signal OUP is enabled.

The third path driving circuit 513 is electrically connected to the through electrode T35 that forms the third signal path. The third path driving circuit 513 drives the through electrode T35, based on the switch signal ST, the even down signal EDN, and the even up signal EUP. The third path driving circuit 513 drives the through electrode T35 through the PMOS transistor (not illustrated) of the third path driving circuit 513 when the switch signal ST is enabled and the even down signal EDN is enabled. The third path driving circuit 513 drives the through electrode T35 through the NMOS transistor (not illustrated) of the third path driving circuit 513 when the switch signal ST is enabled and the even up signal EUP is enabled.

The fourth path driving circuit 514 is electrically connected to the through electrode T45 that forms the fourth signal path. The fourth path driving circuit 514 drives the through electrode T45, based on the switch signal ST, the odd down signal ODN, and the odd up signal OUP. The fourth path driving circuit 514 drives the through electrode T45 through the PMOS transistor (not illustrated) of the fourth path driving circuit 514 when the switch signal ST is enabled and the odd down signal ODN is enabled. The fourth path driving circuit 514 drives the through electrode T45 through the NMOS transistor (not illustrated) of the fourth path driving circuit 514 when the switch signal ST is enabled and the odd up signal OUP is enabled.

FIG. 10 is a diagram illustrating an embodiment of the first path driving circuit 511 that is included in the memory test circuit 51 illustrated in FIG. 9. In an embodiment, the first path driving circuit 511 includes a fifth switch circuit 511-1 and a fifth driving circuit 511-2.

In an embodiment, the fifth switch circuit 511-1 includes an inverter 511<11> and a transfer gate 511<12>. The fifth switch circuit 511-1 connects the through electrode T15 and a node nd511 when the switch signal ST is enabled to a logic high level. The fifth switch circuit 511-1 blocks a connection between the through electrode T15 and the node nd511 when the switch signal ST is disabled to a logic low level.

In an embodiment, the fifth driving circuit 511-2 includes an inverter 511<21>, a PMOS transistor 511<22>, and an NMOS transistor 511<23>. The inverter 511<21> outputs the even down signal EDN by inverting the even down signal EDN. The PMOS transistor 511<22> is connected between the power source voltage VDD and the node nd511, and generates first memory data MD1 having a logic high level by driving the node nd511 to the voltage level of the power source voltage VDD when the output signal of the inverter 511<21> is at a logic low level. The NMOS transistor 511<23> is connected between the node nd511 and the ground voltage VSS, and generates the first memory data MD1 having a logic low level by driving the node nd511 to the voltage level of the ground voltage VSS when the even up signal EUP is at a logic high level. The PMOS transistor 511<22> of the fifth driving circuit 511-2 may be set to have a greater driving force than the NMOS transistor 121<23> of the first fail signal generation circuit 121 in FIG. 5. Accordingly, when a failure does not occur in the through electrodes T11, T12, T13, and T14 that form the first signal path, the fifth driving circuit 511-2 drives the through electrodes T11, T12, T13, and T14 to the voltage level of the power source voltage VDD.

The third path driving circuit 513 illustrated in FIG. 9 is electrically connected to the through electrode T35 and merely drives the through electrode T35, and is implemented with the same circuit as the first path driving circuit 511 illustrated in FIG. 10 and performs the same operation as the first path driving circuit 511 and thus a detailed description thereof is omitted.

FIG. 11 is a diagram illustrating an embodiment of the second path driving circuit 512 that is included in the memory test circuit 51 illustrated in FIG. 9. In an embodiment, the second path driving circuit 512 includes a sixth switch circuit 512-1 and a sixth driving circuit 512-2.

In an embodiment, the sixth switch circuit 512-1 includes an inverter 512<11> and a transfer gate 512<12>. The sixth switch circuit 512-1 connects the through electrode T25 and a node nd512 when the switch signal ST is enabled to a logic high level. The sixth switch circuit 512-1 blocks a connection between the through electrode T25 and the node nd512 when the switch signal ST is disabled to a logic low level.

In an embodiment, the sixth driving circuit 512-2 includes an inverter 512<21>, a PMOS transistor 512<22>, and an NMOS transistor 512<23>. The inverter 512<21> outputs the odd down signal ODN by inverting the odd down signal ODN. For example, the odd down signal ODN output from the inverter 512<21> represents the inversion of the odd down signal ODN input to the inverter 512<21>. The PMOS transistor 512<22> is connected between the power source voltage VDD and the node nd512, and generates second memory data MD2 having a logic high level by driving the node nd512 to the voltage level of the power source voltage VDD when the output signal of the inverter 512<21> is at a logic low level. The NMOS transistor 512<23> is connected between the node nd512 and the ground voltage VSS, and generates the second memory data MD2 having a logic low level by driving the node nd512 to the voltage level of the ground voltage VSS when the odd up signal OUP is at a logic high level. The PMOS transistor 512<22> of the sixth driving circuit 512-2 may be set to have a greater driving force than an NMOS transistor 122<23> of the second fail signal generation circuit 122 in FIG. 6, for example. Accordingly, when a failure does not occur in the through electrodes T11, T12, T13, and T14 that form the first signal path, the sixth driving circuit 512-2 drives the through electrodes T21, T22, T23, and T24 to the voltage level of the power source voltage VDD.

The fourth path driving circuit 514 illustrated in FIG. 9 is electrically connected to the through electrode T45 and merely drives the through electrode T45, and is implemented with the same circuit as the second path driving circuit 512 illustrated in FIG. 11 and performs the same operation as the second path driving circuit 512 and thus a detailed description thereof is omitted.

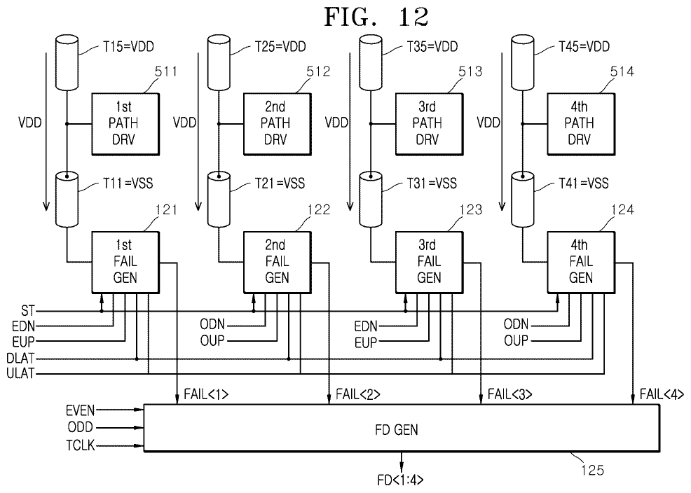

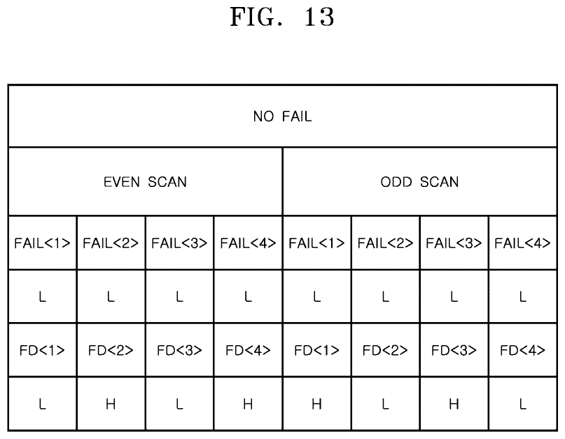

An operation that detects a connection failure of the signal paths of the semiconductor device 1 according to an embodiment of the present disclosure is described with reference to FIGS. 12 and 13. In this case, a case in which a failure is not present (NO FAIL) during an even scan operation EVEN SCAN and an odd scan operation ODD SCAN is described as an example as follows.

After the start of an even scan operation, when the switch signal ST is enabled and the even down signal EDN is enabled, the first fail signal generation circuit 121 drives the through electrode T11 to the voltage level of the ground voltage VSS through the NMOS transistor 121<23> in FIG. 5, for example.

After the start of the even scan operation, when the switch signal ST is enabled and the even down signal EDN is enabled, the first path driving circuit 511 drives the through electrode T15 to the voltage level of the power source voltage VDD through the PMOS transistor 511<22> in FIG. 10, for example.

At this time, the through electrodes T11, T12, T13, T14, and T15 that form the first signal path may be driven to the voltage level of the power source voltage VDD because the PMOS transistor 511<22> of the first path driving circuit 511 is set to have a greater driving force than the NMOS transistor 121<23> of the first fail signal generation circuit 121. The first fail signal generation circuit 121 generates the first fail signal FAIL<1> having a logic low level L when the through electrodes T11, T12, T13, T14, and T15 are driven to the voltage level of the power source voltage VDD.

After the start of the even scan operation, the second fail signal generation circuit 122 generates the second fail signal FAIL<2> having a logic low level L, which is an initial value.

After the start of the even scan operation, when the switch signal ST is enabled and the even down signal EDN is enabled, the third fail signal generation circuit 123 drives the through electrode T31 to the voltage level of the ground voltage VSS through the NMOS transistor (not illustrated) of the third fail signal generation circuit 123.

After the start of the even scan operation, when the switch signal ST is enabled and the even down signal EDN is enabled, the third path driving circuit 513 drives the through electrode T35 to the voltage level of the power source voltage VDD through the PMOS transistor (not illustrated) of the third path driving circuit 513.

At this time, the through electrodes T31, T32, T33, T34, and T35 that form the third signal path may be driven to the voltage level of the power source voltage VDD because the PMOS transistor (not illustrated) of the third path driving circuit 513 is set to have a greater driving force than the NMOS transistor (not illustrated) of the third fail signal generation circuit 123. The third fail signal generation circuit 123 generates the third fail signal FAIL<3> having a logic low level L when the through electrodes T31, T32, T33, T34, and T35 are driven to the voltage level of the power source voltage VDD.

After the start of the even scan operation, the fourth fail signal generation circuit 124 generates the fourth fail signal FAIL<4> having a logic low level L, which is an initial value.

The fail detection signal generation circuit 125 generates the first fail detection signal FD<1> having a logic low level L by non-inverting the first fail signal FAIL<1> based on the odd test signal ODD in synchronization with the test clock TCLK. The fail detection signal generation circuit 125 generates the second fail detection signal FD<2> having a logic high level H by inverting the second fail signal FAIL<2> based on the even test signal EVEN in synchronization with the test clock TCLK. The fail detection signal generation circuit 125 generates the third fail detection signal FD<3> having a logic low level L by non-inverting the third fail signal FAIL<3> based on the odd test signal ODD in synchronization with the test clock TCLK. The fail detection signal generation circuit 125 generates the fourth fail detection signal FD<4> having a logic high level H by inverting the fourth fail signal FAIL<4> based on the even test signal EVEN in synchronization with the test clock TCLK.

A case in which the first fail detection signal FD<1> and the third fail detection signal FD<3> are at a logic low level L after the start of an even scan operation is a case in which a failure is not present. A case in which the first fail detection signal FD<1> and the third fail detection signal FD<3> are at a logic high level H after the start of an even scan operation is a case in which an open failure OPEN occurs. A case in which the second fail detection signal FD<2> and the fourth fail detection signal FD<4> are at a logic high level H after the start of an even scan operation is a case in which a failure is not present. A case in which the second fail detection signal FD<2> and the fourth fail detection signal FD<4> are at a logic low level L after the start of an even scan operation is a case in which a short failure SHORT occurs.

When the first fail detection signal FD<1> having a logic low level L is generated, the fail detection circuit 13 detects that a failure is not present in the through electrodes T11, T12, T13, T14, and T15 that form the first signal path. When the second fail detection signal FD<2> having a logic high level H is generated, the fail detection circuit 13 detects that a failure is not present in the through electrodes T21, T22, T23, T24, and T25 that form the second signal path. When the third fail detection signal FD<3> having a logic low level L is generated, the fail detection circuit 13 detects that a failure is not present in the through electrodes T31, T32, T33, T34, and T35 that form the third signal path. When the fourth fail detection signal FD<4> having a logic high level H is generated, the fail detection circuit 13 detects that a failure is not present in the through electrodes T41, T42, T43, T44, and T45 that form the fourth signal path.

After the start of an odd scan operation, the first fail signal generation circuit 121 generates the first fail signal FAIL<1> having a logic low level L, which is an initial value.

After the start of the odd scan operation, when the switch signal ST is enabled and the odd down signal ODN is enabled, the second fail signal generation circuit 122 drives the through electrode T21 to the voltage level of the ground voltage VSS through the NMOS transistor 122<23> in FIG. 6, for example.

After the start of the odd scan operation, when the switch signal ST is enabled and the odd down signal ODN is enabled, the second path driving circuit 512 drives the through electrode T25 to the voltage level of the power source voltage VDD through the PMOS transistor 512<22> in FIG. 11, for example.

At this time, the through electrodes T21, T22, T23, T24, and T25 that form the second signal path may be driven to the voltage level of the power source voltage VDD because the PMOS transistor 512<22> of the second path driving circuit 512 is set to have a greater driving force than the NMOS transistor 122<23> of the second fail signal generation circuit 122. The second fail signal generation circuit 122 generates the second fail signal FAIL<2> having a logic low level L when the through electrodes T21, T22, T23, T24, and T25 are driven to the voltage level of the power source voltage VDD.

After the start of the odd scan operation, the third fail signal generation circuit 123 generates the third fail signal FAIL<3> having a logic low level L, which is an initial value.

After the start of the odd scan operation, when the switch signal ST is enabled and the odd down signal ODN is enabled, the fourth fail signal generation circuit 124 drives the through electrode T41 to the voltage level of the ground voltage VSS through the NMOS transistor (not illustrated) of the fourth fail signal generation circuit 124.

After the start of the odd scan operation, when the switch signal ST is enabled and the odd down signal ODN is enabled, the fourth path driving circuit 514 drives the through electrode T45 to the voltage level of the power source voltage VDD through the PMOS transistor (not illustrated) of the fourth path driving circuit 514.

At this time, the through electrodes T41, T42, T43, T44, and T45 that form the fourth signal path may be driven to the voltage level of the power source voltage VDD because the PMOS transistor (not illustrated) of the fourth path driving circuit 514 is set to have a greater driving force than the NMOS transistor (not illustrated) of the fourth fail signal generation circuit 124. The fourth fail signal generation circuit 124 generates the fourth fail signal FAIL<4> having a logic low level L when the through electrodes T41, T42, T43, T44, and T45 are driven to the voltage level of the power source voltage VDD.

The fail detection signal generation circuit 125 generates the first fail detection signal FD<1> having a logic high level H by inverting the first fail signal FAIL<1> based on the odd test signal ODD in synchronization with the test clock TCLK. The fail detection signal generation circuit 125 generates the second fail detection signal FD<2> having a logic low level L by non-inverting the second fail signal FAIL<2> based on the even test signal EVEN in synchronization with the test clock TCLK. The fail detection signal generation circuit 125 generates the third fail detection signal FD<3> having a logic high level

H by inverting the third fail signal FAIL<3> based on the odd test signal ODD in synchronization with the test clock TCLK. The fail detection signal generation circuit 125 generates the fourth fail detection signal FD<4> having a logic low level L by non-inverting the fourth fail signal FAIL<4> based on the even test signal EVEN in synchronization with the test clock TCLK.

A case in which the first fail detection signal FD<1> and the third fail detection signal FD<3> are at a logic high level H after the start of an odd scan operation is a case in which a failure is not present. A case in which the first fail detection signal FD<1> and the third fail detection signal FD<3> are at a logic low level L after the start of an odd scan operation is a case in which a short failure SHORT occurs. A case in which the second fail detection signal FD<2> and the fourth fail detection signal FD<4> are at a logic high level H after the start of an odd scan operation is a case in which an open failure OPEN occurs. A case in which the second fail detection signal FD<2> and the fourth fail detection signal FD<4> are at a logic low level L after the start of an odd scan operation is a case in which a failure is not present.

When the first fail detection signal FD<1> having a logic high level H is generated, the fail detection circuit 13 detects that a failure is not present in the through electrodes T11, T12, T13, T14, and T15 that form the first signal path. When the second fail detection signal FD<2> having a logic low level L is generated, the fail detection circuit 13 detects that a failure is not present in the through electrodes T21, T22, T23, T24, and T25 that form the second signal path. When the third fail detection signal FD<3> having a logic high level H is generated, the fail detection circuit 13 detects that a failure is not present in the through electrodes T31, T32, T33, T34, and T35 that form the third signal path. When the fourth fail detection signal FD<4> having a logic low level L is generated, the fail detection circuit 13 detects that a failure is not present in the through electrodes T41, T42, T43, T44, and T45 that form the fourth signal path.

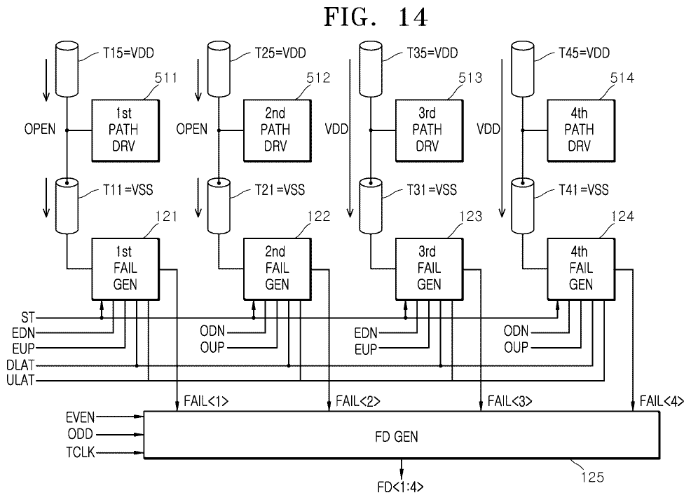

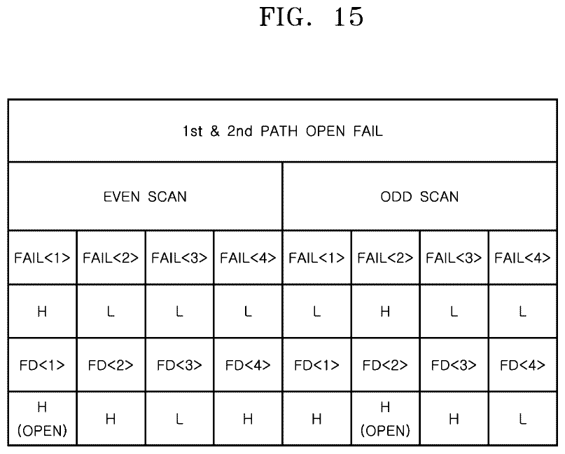

An operation that detects a connection failure of the signal paths of the semiconductor device 1 according to an embodiment of the present disclosure is described with reference to FIGS. 14 and 15. In this case, a case (1^{st} & 2nd PATH OPEN FAIL) in which an open failure occurs in the first signal path and the second signal path during an even scan operation EVEN SCAN and an odd scan operation ODD SCAN is described as an example as follows.

After the start of an even scan operation, when the switch signal ST is enabled and the even down signal EDN is enabled, the first fail signal generation circuit 121 drives the through electrode T11 to the voltage level of the ground voltage VSS through the NMOS transistor 121<23> in FIG. 5, for example.

After the start of the even scan operation, when the switch signal ST is enabled and the even down signal EDN is enabled, the first path driving circuit 511 drives the through electrode T15 to the voltage level of the power source voltage VDD through the PMOS transistor 511<22> in FIG. 10, for example.

At this time, the through electrodes T11, T12, T13, T14, and T15 that form the first signal path are not driven to the voltage level of the power source voltage VDD because an open failure occurs in the through electrodes T11, T12, T13, T14, and T15. The first fail signal generation circuit 121 generates the first fail signal FAIL<1> having a logic high level H because the through electrodes T11, T12, T13, T14, and T15 are not driven to the voltage level of the power source voltage VDD.

After the start of an even scan operation, the second fail signal generation circuit 122 generates the second fail signal FAIL<2> having a logic low level L, which is an initial value.

After the start of the even scan operation, when the switch signal ST is enabled and the even down signal EDN is enabled, the third fail signal generation circuit 123 drives the through electrode T31 to the voltage level of the ground voltage VSS through the NMOS transistor (not illustrated) of the third fail signal generation circuit 123.

After the start of the even scan operation, when the switch signal ST is enabled and the even down signal EDN is enabled, the third path driving circuit 513 drives the through electrode T35 to the voltage level of the power source voltage VDD through the PMOS transistor (not illustrated) of the third path driving circuit 513.

At this time, the through electrodes T31, T32, T33, T34, and T35 that form the third signal path may be driven to the voltage level of the power source voltage VDD because the PMOS transistor (not illustrated) of the third path driving circuit 513 is set to have a greater driving force than the NMOS transistor (not illustrated) of the third fail signal generation circuit 123. When the through electrodes T31, T32, T33, T34, and T35 are driven to the voltage level of the power source voltage VDD, the third fail signal generation circuit 123 generates the third fail signal FAIL<3> having a logic low level L.

After the start of the even scan operation, the fourth fail signal generation circuit 124 generates the fourth fail signal FAIL<4> having a logic low level L, which is an initial value.

The fail detection signal generation circuit 125 generates the first fail detection signal FD<1> having a logic high level H by non-inverting the first fail signal FAIL<1> based on the odd test signal ODD in synchronization with the test clock TCLK. The fail detection signal generation circuit 125 generates the second fail detection signal FD<2> having a logic high level H by inverting the second fail signal FAIL<2> based on the even test signal EVEN in synchronization with the test clock TCLK. The fail detection signal generation circuit 125 generates the third fail detection signal FD<3> having a logic low level L by non-inverting the third fail signal FAIL<3> based on the odd test signal ODD in synchronization with the test clock TCLK. The fail detection signal generation circuit 125 generates the fourth fail detection signal FD<4> having a logic high level H by inverting the fourth fail signal FAIL<4> based on the even test signal EVEN in synchronization with the test clock TCLK.

A case in which the first fail detection signal FD<1> and the third fail detection signal FD<3> are at a logic low level L after the start of an even scan operation is a case in which a failure is not present. A case in which the first fail detection signal FD<1> and the third fail detection signal FD<3> are at a logic high level H after the start of an even scan operation is a case in which an open failure OPEN occurs. A case in which the second fail detection signal FD<2> and the fourth fail detection signal FD<4> are at a logic high level H after the start of an even scan operation is a case in which a failure is not present. A case in which the second fail detection signal FD<2> and the fourth fail detection signal FD<4> are at a logic low level L after the start of an even scan operation is a case in which a short failure SHORT occurs.

When the first fail detection signal FD<1> having a logic high level H is generated, the fail detection circuit 13 detects that an open failure OPEN occurs in the through electrodes T11, T12, T13, T14, and T15 that form the first signal path. When the second fail detection signal FD<2> having a logic high level H is generated, the fail detection circuit 13 detects that a failure is not present in the through electrodes T21, T22, T23, T24, and T25 that form the second signal path. When the third fail detection signal FD<3> having a logic low level L is generated, the fail detection circuit 13 detects that a failure is not present in the through electrodes T31, T32, T33, T34, and T35 that form the third signal path. When the fourth fail detection signal FD<4> having a logic high level H is generated, the fail detection circuit 13 detects that a failure is not present in the through electrodes T41, T42, T43, T44, and T45 that form the fourth signal path.

After the start of an odd scan operation, the first fail signal generation circuit 121 generates the first fail signal FAIL<1> having a logic low level L, which is an initial value.

After the start of the odd scan operation, when the switch signal ST is enabled and the odd down signal ODN is enabled, the second fail signal generation circuit 122 drives the through electrode T21 to the voltage level of the ground voltage VSS through the NMOS transistor 122<23> in FIG. 6, for example.

After the start of the odd scan operation, when the switch signal ST is enabled and the odd down signal ODN is enabled, the second path driving circuit 512 drives the through electrode T25 to the voltage level of the power source voltage VDD through the PMOS transistor 512<22> in FIG. 11, for example.

At this time, the through electrodes T21, T22, T23, T24, and T25 that form the second signal path are not driven to the voltage level of the power source voltage VDD. The second fail signal generation circuit 122 generates the second fail signal FAIL<2> having a logic high level H because the through electrodes T21, T22, T23, T24, and T25 are not driven to the voltage level of the power source voltage VDD.

After the start of an odd scan operation, the third fail signal generation circuit 123 generates the third fail signal FAIL<3> having a logic low level L, which is an initial value.

After the start of the odd scan operation, when the switch signal ST is enabled and the odd down signal ODN is enabled, the fourth fail signal generation circuit 124 drives the through electrode T41 to the voltage level of the ground voltage VSS through the NMOS transistor (not illustrated) of the fourth fail signal generation circuit 124.

After the start of the odd scan operation, when the switch signal ST is enabled and the odd down signal ODN is enabled, the fourth path driving circuit 514 drives the through electrode T45 to the voltage level of the power source voltage VDD through the PMOS transistor (not illustrated) of the fourth path driving circuit 514.

At this time, the through electrodes T41, T42, T43, T44, and T45 that form the fourth signal path may be driven to the voltage level of the power source voltage VDD because the PMOS transistor (not illustrated) of the fourth path driving circuit 514 is set to have a greater driving force than the NMOS transistor (not illustrated) of the fourth fail signal generation circuit 124. The fourth fail signal generation circuit 124 generates the fourth fail signal FAIL<4> having a logic low level L when the through electrodes T41, T42, T43, T44, and T45 are driven to the voltage level of the power source voltage VDD.

The fail detection signal generation circuit 125 generates the first fail detection signal FD<1> having a logic high level H by inverting the first fail signal FAIL<1> based on the odd test signal ODD in synchronization with the test clock TCLK. The fail detection signal generation circuit 125 generates the second fail detection signal FD<2> having a logic high level H by non-inverting the second fail signal FAIL<2> based on the even test signal EVEN in synchronization with the test clock TCLK. The fail detection signal generation circuit 125 generates the third fail detection signal FD<3> having a logic high level H by inverting the third fail signal FAIL<3> based on the odd test signal ODD in synchronization with the test clock TCLK. The fail detection signal generation circuit 125 generates the fourth fail detection signal FD<4> having a logic low level L by non-inverting the fourth fail signal FAIL<4> based on the even test signal EVEN in synchronization with the test clock TCLK.

A case in which the first fail detection signal FD<1> and the third fail detection signal FD<3> are at a logic high level H after the start of an odd scan operation is a case in which a failure is not present.

A case in which the first fail detection signal FD<1> and the third fail detection signal FD<3> are at a logic low level L after the start of an odd scan operation is a case in which a short failure SHORT occurs. A case in which the second fail detection signal FD<2> and the fourth fail detection signal FD<4> are at a logic high level H after the start of an odd scan operation is a case in which an open failure OPEN occurs. A case in which the second fail detection signal FD<2> and the fourth fail detection signal FD<4> are at a logic low level L after the start of an odd scan operation is a case in which a failure is not present.

When the first fail detection signal FD<1> having a logic high level H is generated, the fail detection circuit 13 detects that a failure is not present in the through electrodes T11, T12, T13, T14, and T15 that form the first signal path. When the second fail detection signal FD<2> having a logic high level H is generated, the fail detection circuit 13 detects that an open failure OPEN occurs in the through electrodes T21, T22, T23, T24, and T15 that form the second signal path. When the third fail detection signal FD<3> having a logic high level H is generated, the fail detection circuit 13 detects that a failure is not present in the through electrodes T31, T32, T33, T34, and T35 that form the third signal path. When the fourth fail detection signal FD<4> having a logic low level L is generated, the fail detection circuit 13 detects that a failure is not present in the through electrodes T41, T42, T43, T44, and T45 that form the fourth signal path.

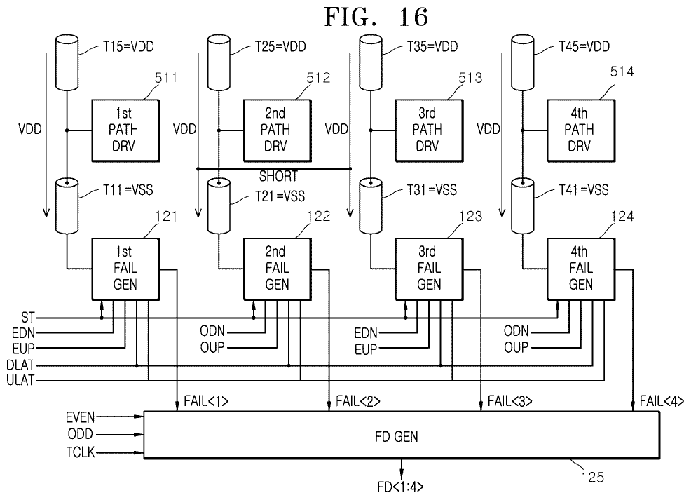

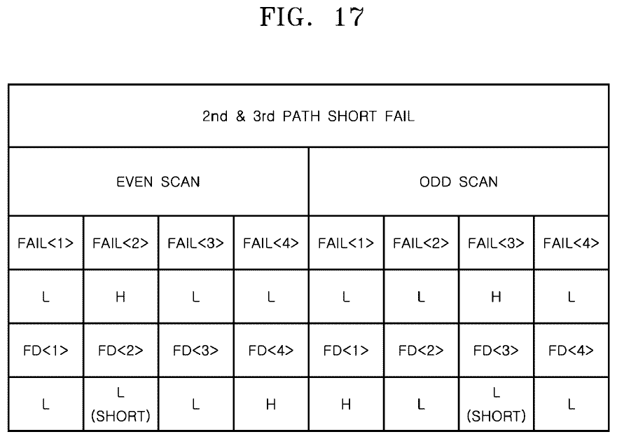

An operation that detects a connection failure of the signal paths of the semiconductor device 1 according to an embodiment of the present disclosure is described with reference to FIGS. 16 and 17. In this case, a case (2^{nd} & 3^{rd} PATH SHORT FAIL) in which a short failure occurs in the second signal path and the third signal path during an even scan operation EVEN SCAN and an odd scan operation ODD SCAN is described as an example as follows.

After the start of an even scan operation, when the switch signal ST is enabled and the even down signal EDN is enabled, the first fail signal generation circuit 121 drives the through electrode T11 to the voltage level of the ground voltage VSS through the NMOS transistor 121<23> in FIG. 5, for example.

After the start of the even scan operation, when the switch signal ST is enabled and the even down signal EDN is enabled, the first path driving circuit 511 drives the through electrode T15 to the voltage level of the power source voltage VDD through the PMOS transistor 511<22> in FIG. 10, for example.

At this time, the through electrodes T11, T12, T13, T14, and T15 that form the first signal path may be driven to the voltage level of the power source voltage VDD because the PMOS transistor 511<22> of the first path driving circuit 511 is set to have a greater driving force than the NMOS transistor 121<23> of the first fail signal generation circuit 121. The first fail signal generation circuit 121 generates the first fail signal FAIL<1>having a logic low level L when the through electrodes T11, T12, T13, T14, and T15 are driven to the voltage level of the power source voltage VDD.

The second fail signal generation circuit 122 needs to generate the second fail signal FAIL<2> having a logic low level L, which is an initial value, after the start of an even scan operation, but generates the second fail signal FAIL<2> having a logic high level H because a short failure occurs in the second signal path and the third signal path.

After the start of an even scan operation, when the switch signal ST is enabled and the even down signal EDN is enabled, the third fail signal generation circuit 123 drives the through electrode T31 to the voltage level of the ground voltage VSS through the NMOS transistor (not illustrated) of the third fail signal generation circuit 123.

After the start of the even scan operation, when the switch signal ST is enabled and the even down signal EDN is enabled, the third path driving circuit 513 drives the through electrode T35 to the voltage level of the power source voltage VDD through the PMOS transistor (not illustrated) of the third path driving circuit 513.

At this time, the through electrodes T31, T32, T33, T34, and T35 that form the third signal path are not driven to the voltage level of the power source voltage VDD. The third fail signal generation circuit 123 generates the third fail signal FAIL<3> having a logic low level L when the through electrodes T31, T32, T33, T34, and T35 are not driven to the voltage level of the power source voltage VDD.

The fourth fail signal generation circuit 124 generates the fourth fail signal FAIL<4> having a logic low level L, which is an initial value, after the start of an even scan operation.

The fail detection signal generation circuit 125 generates the first fail detection signal FD<1> having a logic low level L by non-inverting the first fail signal FAIL<1> based on the odd test signal ODD in synchronization with the test clock TCLK. The fail detection signal generation circuit 125 generates the second fail detection signal FD<2> having a logic low level L by inverting the second fail signal FAIL<2> based on the even test signal EVEN in synchronization with the test clock TCLK. The fail detection signal generation circuit 125 generates the third fail detection signal FD<3> having a logic low level L by non-inverting the third fail signal FAIL<3> based on the odd test signal ODD in synchronization with the test clock TCLK. The fail detection signal generation circuit 125 generates the fourth fail detection signal FD<4> having a logic high level H by inverting the fourth fail signal FAIL<4> based on the even test signal EVEN in synchronization with the test clock TCLK.

A case in which the first fail detection signal FD<1> and the third fail detection signal FD<3> are at a logic low level L after the start of an even scan operation is a case in which a failure is not present. A case in which the first fail detection signal FD<1> and the third fail detection signal FD<3> are at a logic high level H after the start of an even scan operation is a case in which an open failure OPEN occurs. A case in which the second fail detection signal FD<2> and the fourth fail detection signal FD<4> are at a logic high level H after the start of an even scan operation is a case in which a failure is not present. A case in which the second fail detection signal FD<2> and the fourth fail detection signal FD<4> are at a logic low level L after the start of an even scan operation is a case in which a short failure SHORT occurs.

When the first fail detection signal FD<1> having a logic low level L is generated, the fail detection circuit 13 detects that a failure is not present in the through electrodes T11, T12, T13, T14, and T15 that form the first signal path. When the second fail detection signal FD<2> having a logic low level L is generated, the fail detection circuit 13 detects that a short failure SHORT occurs in the through electrodes T21, T22, T23, T24, and T25 that form the second signal path. When the third fail detection signal FD<3> having a logic low level L is generated, the fail detection circuit 13 detects that a failure is not present in the through electrodes T31, T32, T33, T34, and T35 that form the third signal path. When the fourth fail detection signal FD<4> having a logic high level H is generated, the fail detection circuit 13 detects that a failure is not present in the through electrodes T41, T42, T43, T44, and T45 that form the fourth signal path.

The first fail signal generation circuit 121 generates the first fail signal FAIL<1> having a logic low level L, which is an initial value, after the start of an odd scan operation.

After the start of the odd scan operation, when the switch signal ST is enabled and the odd down signal ODN is enabled, the second fail signal generation circuit 122 drives the through electrode T21 to the voltage level of the ground voltage VSS through the NMOS transistor 122<23> in FIG. 6, for example.

After the start of the odd scan operation, when the switch signal ST is enabled and the odd down signal ODN is enabled, the second path driving circuit 512 drives the through electrode T25 to the voltage level of the power source voltage VDD through the PMOS transistor 512<22> in FIG. 11, for example.

At this time, the through electrodes T21, T22, T23, T24, and T25 that form the second signal path may be driven to the voltage level of the power source voltage VDD because the PMOS transistor 512<22> of the second path driving circuit 512 is set to have a greater driving force than the NMOS transistor 122<23> of the second fail signal generation circuit 122. The second fail signal generation circuit 122 generates the second fail signal FAIL<2> having a logic low level L when the through electrodes T21, T22, T23, T24, and T25 are driven to the voltage level of the power source voltage VDD.

The third fail signal generation circuit 123 needs to generate the third fail signal FAIL<3> having a logic low level L, which is an initial value, after the start of an odd scan operation, but generates the third fail signal FAIL<3> having a logic high level H because a short failure occurs in the second signal path and the third signal path.

After the start of the odd scan operation, when the switch signal ST is enabled and the odd down signal ODN is enabled, the fourth fail signal generation circuit 124 drives the through electrode T41 to the voltage level of the ground voltage VSS through the NMOS transistor (not illustrated) of the fourth fail signal generation circuit 124.

After the start of the odd scan operation, when the switch signal ST is enabled and the odd down signal ODN is enabled, the fourth path driving circuit 514 drives the through electrode T45 to the voltage level of the power source voltage VDD through the PMOS transistor (not illustrated) of the fourth path driving circuit 514.

At this time, the through electrodes T41, T42, T43, T44, and T45 that form the fourth signal path may be driven to the voltage level of the power source voltage VDD because the PMOS transistor (not illustrated) of the fourth path driving circuit 514 is set to have a greater driving force than the NMOS transistor (not illustrated) of the fourth fail signal generation circuit 124. The fourth fail signal generation circuit 124 generates the fourth fail signal FAIL<4> having a logic low level L when the through electrodes T41, T42, T43, T44, and T45 are driven to the voltage level of the power source voltage VDD.

The fail detection signal generation circuit 125 generates the first fail detection signal FD<1> having a logic high level H by inverting the first fail signal FAIL<1> based on the odd test signal ODD in synchronization with the test clock TCLK. The fail detection signal generation circuit 125 generates the second fail detection signal FD<2> having a logic low level L by non-inverting the second fail signal FAIL<2> based on the even test signal EVEN in synchronization with the test clock TCLK. The fail detection signal generation circuit 125 generates the third fail detection signal FD<3> having a logic low level L by inverting the third fail signal FAIL<3> based on the odd test signal ODD in synchronization with the test clock TCLK. The fail detection signal generation circuit 125 generates the fourth fail detection signal FD<4> having a logic low level L by non-inverting the fourth fail signal FAIL<4> based on the even test signal EVEN in synchronization with the test clock TCLK.

A case in which the first fail detection signal FD<1> and the third fail detection signal FD<3> are at a logic high level H after the start of an odd scan operation is a case in which a failure is not present. A case in which the first fail detection signal FD<1> and the third fail detection signal FD<3> are at a logic low level L after the start of an odd scan operation is a case in which a short failure SHORT occurs. A case in which the second fail detection signal FD<2> and the fourth fail detection signal FD<4> are at a logic high level H after the start of an odd scan operation is a case in which an open failure OPEN occurs. A case in which the second fail detection signal FD<2> and the fourth fail detection signal FD<4> are at a logic low level L after the start of an odd scan operation is a case in which a failure is not present.

When the first fail detection signal FD<1> having a logic high level H is generated, the fail detection circuit 13 detects that a failure is not present in the through electrodes T11, T12, T13, T14, and T15 that form the first signal path. When the second fail detection signal FD<2> having a logic low level L is generated, the fail detection circuit 13 detects that a failure is not present in the through electrodes T21, T22, T23, T24, and T25 that form the second signal path. When the third fail detection signal FD<3> having a logic low level L is generated, the fail detection circuit 13 detects that an open failure OPEN occurs in the through electrodes T31, T32, T33, T34, and T35 that form the third signal path. When the fourth fail detection signal FD<4> having a logic low level L is generated, the fail detection circuit 13 detects that a failure is not present in the through electrodes T41, T42, T43, T44, and T45 that form the fourth signal path.

As described above, the semiconductor device 1 according to an embodiment of the present disclosure can detect a connection failure of a plurality of signal paths by performing an even scan operation and an odd scan operation on the plurality of signal paths and then detecting the logic levels of the plurality of signal paths. The semiconductor device 1 can detect an open failure and short failure of a plurality of signal paths by sequentially performing an even scan operation and an odd scan operation on the plurality of signal paths and detecting the logic levels of the plurality of signal paths. The semiconductor device 1 can reduce a test time by detecting an open failure and short failure of a plurality of signal paths in a way to perform an even scan operation on a plurality of signal paths that are not consecutive to each other and then perform an odd scan operation on a plurality of the remaining signal paths.

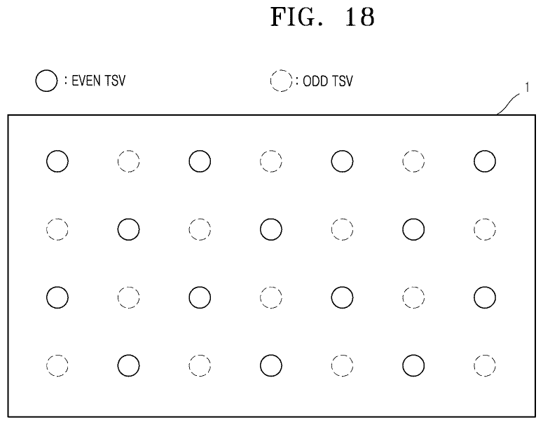

FIG. 18 is an arrangement diagram, which is viewed from the top of the semiconductor device 1, illustrating the locations of a plurality of signal paths according to an embodiment of the present disclosure.

In an embodiment, the semiconductor device 1 includes a plurality of even through electrodes EVEN TSV and a plurality of odd through electrodes ODD TSV.

The plurality of even through electrodes EVEN TSV and the plurality of odd through electrodes ODD TSV that are included in the semiconductor device 1 are disposed to be consecutive to each other. As illustrated in FIG. 18, for example, an even through electrode EVEN TSV has an odd through electrodes ODD TSV above, below, to the right, and to the left of the even through electrode EVEN TSV.

The plurality of even through electrodes EVEN TSV that is included in the semiconductor device 1 is not disposed in an orthogonal direction with respect to each other. The plurality of even through electrodes EVEN TSV that is included in the semiconductor device 1 is disposed in a diagonal direction with respect to each other.

The plurality of odd through electrodes ODD TSV that are included in the semiconductor device 1 is not disposed in an orthogonal direction with respect to each other. The plurality of odd through electrodes ODD TSV that are included in the semiconductor device 1 is disposed in a diagonal direction with respect to each other.

For example, the plurality of even through electrodes EVEN TSV illustrated in FIG. 18 is implemented with the through electrodes T11, T12, T13, and T14 that form the first signal path, which are illustrated in FIG. 1 and the through electrodes T31, T32, T33, and T34 that form the third signal path, which are illustrated in FIG. 1. For example, the plurality of odd through electrodes ODD TSV illustrated in FIG. 18 is implemented with the through electrodes T21, T22, T23, and T24 that form the second signal path, which are illustrated in FIG. 1, and the through electrodes T41, T42, T43, and T44 that form the fourth signal path, which are illustrated in FIG. 1.

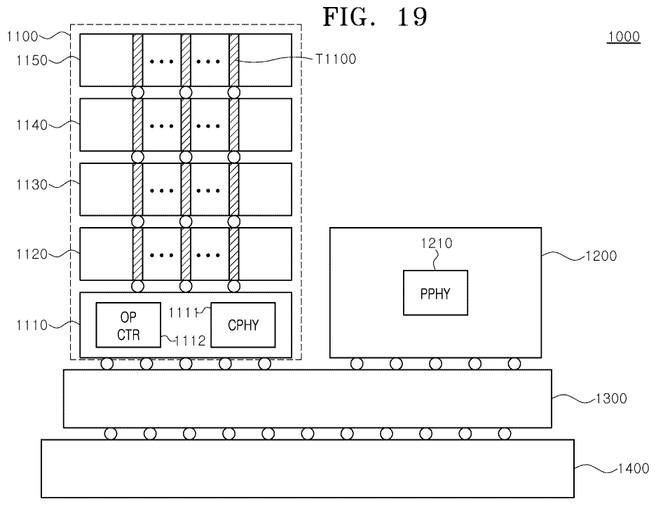

FIG. 19 is a block diagram illustrating a stack memory system 1000 according to an embodiment of the present disclosure. As illustrated in FIG. 19, a stack memory system 1000 includes a semiconductor device 1100, a processor 1200, an interposer 1300, and a board 1400.

The interposer 1300 is formed on or over the board 1400. The semiconductor device 1100 and the processor 1200 are formed on or over the interposer 1300. The interposer 1300 is used to electrically connect the board 1400, the semiconductor device 1100, and the processor 1200. The board 1400, the semiconductor device 1100, and the processor 1200 are electrically connected by using the interposer 1300 including wires that are variously formed because differences between the pitches of the board 1400, the semiconductor device 1100, and the processor 1200 are great.

In an embodiment, the processor 1200 includes a processor interface circuit (PPHY) 1210. The processor 1200 applies a signal including a command and an address that control various internal operations of the semiconductor device 1100 to the semiconductor device 1100 through the processor interface circuit 1210, and the processor 1200 receives data from the semiconductor device 1100 through the processor interface circuit 1210.

In an embodiment, the semiconductor device 1100 includes a base chip 1110 and memory chips 1120, 1130, 1140, and 1150. The semiconductor device 1100 is implemented with the semiconductor device 1 illustrated in FIG. 1, for example.

The memory chips 1120, 1130, 1140, and 1150 are sequentially stacked on or over the base chip 1110. Each of the memory chips 1120, 1130, 1140, and 1150 receives various signals from the base chip 1110 through through electrodes T1100.

In an embodiment, the base chip 1110 includes a core interface circuit (CPHY) 1111 and an operation control circuit (OP CTR) 1112. The core interface circuit 1111 is configured to be capable of communicating with the processor interface circuit 1112, and transmits, to the operation control circuit 1112, a signal including a command and an address that are transmitted by the processor 1200 and applies, to the processor 1200, data that are generated by the operation control circuit 1112. The core interface circuit 1111 is implemented with the test signal generation circuit 11 and the logic test circuit 12 illustrated in FIG. 2, for example. The operation control circuit 1112 is implemented with the test signal generation circuit 11, the logic test circuit 12, and the fail detection circuit 13 which are illustrated in FIG. 2, for example.

The semiconductor device 1100 detects a connection failure of a plurality of signal paths by performing an even scan operation and an odd scan operation on the plurality of signal paths that are connected to the plurality of memory chips 1120, 1130, 1140, and 1150 and then detecting the logic levels of the plurality of signal paths. The semiconductor device 1100 detects an open failure and short failure of a plurality of signal paths by sequentially performing an even scan operation and an odd scan operation on the plurality of signal paths that are connected to the plurality of memory chips 1120, 1130, 1140, and 1150 and detecting the logic levels of the plurality of signal paths. The semiconductor device 1100 can reduce a test time by detecting an open failure and short failure of a plurality of signal paths in a way to perform an even scan operation on a plurality of signal paths that are connected to the plurality of memory chips 1120, 1130, 1140, and 1150 and that are not consecutive to each other and then perform an odd scan operation on a plurality of the remaining signal paths.

Some embodiments of the present disclosure have been described so far. A person having ordinary knowledge in the art to which the present teachings pertain will understand that the present teachings may be implemented in a modified form without departing from an intrinsic characteristic of the present disclosure. Accordingly, the disclosed embodiments should be considered from a descriptive viewpoint, not from a limitative viewpoint. The scope of the present disclosure is determined from the claims not the aforementioned description, and all differences within an equivalent range thereof should be construed as being included in the present disclosure.

What is claimed is:

1. A semiconductor device comprising:
a base chip and a memory chip stacked with first, second, third, and fourth signal paths, each signal path extending through the memory chip into the base chip,
wherein the base chip and the memory chip are configured to simultaneously drive the first signal path and the third signal path after the start of an even scan operation and then simultaneously drive the second signal path and the fourth signal path after a start of an odd scan operation, and
wherein the base chip is configured to generate first, second, third, and fourth fail detection signals that detect a connection failure of the first, second, third, and fourth signal paths, respectively, based on a logic level at which the first, second, third, and fourth signal paths are driven.

2. The semiconductor device of claim 1, wherein:
the second signal path is disposed between the first signal path and the third signal path, and
the third signal path is disposed between the second signal path and the fourth signal path.

3. The semiconductor device of claim 1, wherein:
each of the first, second, third, and fourth signal paths comprises multiple through electrodes and multiple bumps, and
the multiple through electrodes and the multiple bumps included in each of the first, second, third, and fourth signal paths are electrically connected to each other.

4. The semiconductor device of claim 1, wherein the base chip comprises:
a logic test circuit configured to generate the first, second, third, and fourth fail detection signals by driving the first signal path through any one of a first PMOS transistor and a first NMOS transistor and driving the third signal path through any one of a third PMOS transistor and a third NMOS transistor, after the start of the even scan operation, and then driving the second signal path through any one of a second PMOS transistor and a second NMOS transistor and driving the fourth signal path through any one of a fourth PMOS transistor and a fourth NMOS transistor, after the start of the odd scan operation; and
a fail detection circuit configured to detect a connection failure of the first, second, third, and fourth signal paths by detecting logic levels of the first, second, third, and fourth fail detection signals.

5. The semiconductor device of claim 4, wherein the logic test circuit comprises:
a first fail signal generation circuit configured to generate a first fail signal by driving the first signal path through any one of the first PMOS transistor and the first NMOS transistor based on an even down signal and an even up signal;
a second fail signal generation circuit configured to generate a second fail signal by driving the second signal path through any one of the second PMOS transistor and the second NMOS transistor based on an odd down signal and an odd up signal;
a third fail signal generation circuit configured to generate a third fail signal by driving the third signal path through any one of the third PMOS transistor and the third NMOS transistor based on the even down signal and the even up signal;
a fourth fail signal generation circuit configured to generate a fourth fail signal by driving the fourth signal path through any one of the fourth PMOS transistor and the fourth NMOS transistor based on the odd down signal and the odd up signal; and
a fail detection signal generation circuit configured to output the first, second, third, and fourth fail signals as the first, second, third, and fourth fail detection signals by serializing the first, second, third, and fourth fail signals based on an even test signal and an odd test signal in synchronization with a test clock.

6. The semiconductor device of claim 5, wherein the first fail signal generation circuit comprises:
a first switch circuit configured to connect the first signal path and a first node when a switch signal is enabled;
a first driving circuit configured to generate first base data by driving the first node through any one of the first PMOS transistor and the first NMOS transistor based on the even down signal and the even up signal; and
a first storage circuit configured to store the first base data based on a down latch signal and an up latch signal and configured to generate the first fail signal from the first base data that have been stored.

7. The semiconductor device of claim 5, wherein the second fail signal generation circuit comprises:
a second switch circuit configured to connect the second signal path and a second node when the switch signal is enabled;
a second driving circuit configured to generate second base data by driving the second node through any one of the second PMOS transistor and the second NMOS transistor based on the odd down signal and the odd up signal; and
a second storage circuit configured to store the second base data based on a down latch signal and an up latch signal and configured to generate the second fail signal from the second base data that have been stored.

8. The semiconductor device of claim 5, wherein the third fail signal generation circuit comprises:
a third switch circuit configured to connect the third signal path and a third node when a switch signal is enabled;
a third driving circuit configured to generate third base data by driving the third node through any one of the third PMOS transistor and the third NMOS transistor based on the even down signal and the even up signal; and
a third storage circuit configured to store the third base data based on a down latch signal and an up latch signal and configured to generate the third fail signal from the third base data that have been stored.

9. The semiconductor device of claim 5, wherein the fourth fail signal generation circuit comprises:
a fourth switch circuit configured to connect the fourth signal path and a fourth node when a switch signal is enabled;
a fourth driving circuit configured to generate fourth base data by driving the fourth node through any one of the fourth PMOS transistor and the fourth NMOS transistor based on the odd down signal and the odd up signal; and
a fourth storage circuit configured to store the fourth base data based on a down latch signal and an up latch signal and configured to generate the fourth fail signal from the fourth base data that have been stored.

10. The semiconductor device of claim 5, wherein the fail detection signal generation circuit is configured to, in synchronization with the test clock:
output the third fail signal as the third fail detection signal after outputting the fourth fail signal as the fourth fail detection signal,
output the second fail signal as the second fail detection signal after outputting the third fail signal as the third fail detection signal, and
output the first fail signal as the first fail detection signal after outputting the second fail signal as the second fail detection signal.

11. The semiconductor device of claim 1, wherein the memory chip comprises a memory test circuit configured to drive the first signal path through any one of a fifth PMOS transistor and a fifth NMOS transistor and drive the third signal path through any one of a seventh PMOS transistor and a seventh NMOS transistor, after the start of the even scan operation, and configured to then drive the second signal path through any one of a sixth PMOS transistor and a sixth NMOS transistor and drive the fourth signal path through any one of an eighth PMOS transistor and an eighth NMOS transistor, after the start of the odd scan operation.

12. The semiconductor device of claim 11, wherein the memory test circuit comprises:
a first path driving circuit comprising the fifth PMOS transistor and the fifth NMOS transistor and configured to drive the first signal path through any one of the fifth PMOS transistor and the fifth NMOS transistor based on an even down signal and an even up signal;
a second path driving circuit comprising the sixth PMOS transistor and the sixth NMOS transistor and configured to drive the second signal path through any one of the sixth PMOS transistor and the sixth NMOS transistor based on an odd down signal and an odd up signal;
a third path driving circuit comprising the seventh PMOS transistor and the seventh NMOS transistor and configured to drive the third signal path through any one of the seventh PMOS transistor and the seventh NMOS transistor based on the even down signal and the even up signal; and
a fourth path driving circuit comprising the eighth PMOS transistor and the eighth NMOS transistor and configured to drive the fourth signal path through any one of the eighth PMOS transistor and the eighth NMOS transistor based on the odd down signal and the odd up signal.

13. The semiconductor device of claim 12, wherein the first path driving circuit comprises:
a fifth switch circuit configured to connect the first signal path and a fifth node when a switch signal is enabled; and
a fifth driving circuit configured to generate first memory data by driving the fifth node through any one of the fifth PMOS transistor and the fifth NMOS transistor based on the even down signal and the even up signal.

14. The semiconductor device of claim 12, wherein the second path driving circuit comprises:
a sixth switch circuit configured to connect the second signal path and a sixth node when a switch signal is enabled; and
a sixth driving circuit configured to generate second memory data by driving the sixth node through any one of the sixth PMOS transistor and the sixth NMOS transistor based on the odd down signal and the odd up signal.

15. The semiconductor device of claim 12, wherein the third path driving circuit comprises:
a seventh switch circuit configured to connect the third signal path and a seventh node when a switch signal is enabled; and
a seventh driving circuit configured to generate third memory data by driving the seventh node through any one of the seventh PMOS transistor and the seventh NMOS transistor based on the even down signal and the even up signal.

16. The semiconductor device of claim 12, wherein the fourth path driving circuit comprises:
an eighth switch circuit configured to connect the fourth signal path and an eighth node when a switch signal is enabled; and
an eighth driving circuit configured to generate fourth memory data by driving the eighth node through any one of the eighth PMOS transistor and the eighth NMOS transistor based on the odd down signal and the odd up signal.

17. A semiconductor device comprising:
a memory chip configured to simultaneously drive first and third signal paths through first and third PMOS transistors and configured to simultaneously drive second and fourth signal paths through second and fourth PMOS transistors; and
a base chip configured to simultaneously drive the first and third signal paths through first and third NMOS transistors, configured to simultaneously drive the second and fourth signal paths through second and fourth NMOS transistors, and configured to detect a connection failure of the first, second, third, and fourth signal paths by detecting logic levels at which the first, second, third, and fourth signal paths are driven.

18. The semiconductor device of claim 17, wherein the base chip and the memory chip are electrically connected through the first, second, third, and fourth signal paths.

19. The semiconductor device of claim 17, wherein the base chip and the memory chip are stacked with the first, second, third, and fourth signal paths extending through the memory chip into the base chip.

20. The semiconductor device of claim 17, wherein:
the base chip is configured to detect that an open failure in which the first signal path is disconnected occurred when the first signal path is driven to a second logic level through the first PMOS transistor and the first NMOS transistor,
the base chip is configured to detect that an open failure in which the second signal path is disconnected occurred when the second signal path is driven to the second logic level through the second PMOS transistor and the second NMOS transistor,
the base chip is configured to detect that an open failure in which the third signal path is disconnected occurred when the third signal path is driven to the second logic level through the third PMOS transistor and the third NMOS transistor, and
the base chip is configured to detect that an open failure in which the fourth signal path is disconnected occurred when the fourth signal path is driven to the second logic level through the fourth PMOS transistor and the fourth NMOS transistor.

21. The semiconductor device of claim 17, wherein:
the base chip is configured to detect that a short failure in which the first signal path and the second signal path are connected occurred when the second signal path is driven to a second logic level through the second PMOS transistor and the second NMOS transistor after the first signal path is driven to a first logic level through the first PMOS transistor and the first NMOS transistor, and
the base chip is configured to detect that a short failure in which the third signal path and the fourth signal path are connected occurred when the fourth signal path is driven to the second logic level through the fourth PMOS transistor and the fourth NMOS transistor after the third signal path is driven to the first logic level through the third PMOS transistor and the third NMOS transistor.

22. The semiconductor device of claim 17, wherein:
the memory chip is configured to drive the first and third signal paths through fifth and seventh NMOS transistors and drive the second and fourth signal paths through sixth and eighth NMOS transistors, and
the base chip is configured to drive the first and third signal paths through fifth and seventh PMOS transistors and drive the second and fourth signal paths through sixth and eighth PMOS transistors.

23. The semiconductor device of claim 22, wherein:
the base chip is configured to detect that an open failure in which the first signal path is disconnected occurred when the first signal path is driven to a second logic level through the fifth NMOS transistor and the fifth PMOS transistor,
the base chip is configured to detect that an open failure in which the second signal path is disconnected occurred when the second signal path is driven to the second logic level through the sixth NMOS transistor and the sixth PMOS transistor,
the base chip is configured to detect that an open failure in which the third signal path is disconnected occurred when the third signal path is driven to the second logic level through the seventh NMOS transistor and the seventh PMOS transistor, and
the base chip is configured to detect that an open failure in which the fourth signal path is disconnected occurred when the fourth signal path is driven to the second logic level through the eighth NMOS transistor and the eighth PMOS transistor.

24. The semiconductor device of claim 22, wherein:
the base chip is configured to detect that a short failure in which the first signal path and the second signal path are connected occurred when the second signal path is driven to a second logic level through the sixth NMOS transistor and the sixth PMOS transistor after the first signal path is driven to a first logic level through the fifth NMOS transistor and the fifth PMOS transistor, and
the base chip is configured to detect that a short failure in which the third signal path and the fourth signal path are connected occurred when the fourth signal path is driven to the second logic level through the eighth NMOS transistor and the eighth PMOS transistor after the third signal path is driven to the first logic level through the seventh NMOS transistor and the seventh PMOS transistor.
